(19) United States
(12) Patent Application Publication
(10) Pub. No.: US 2025/0098494 A1
(43) Pub. Date: Mar. 20, 2025

(54) DISPLAY DEVICE

(71) Applicant: Samsung Display Co., LTD., Yongin-si (KR)

(72) Inventors: Nam Su KANG, Yongin-si (KR); Seung Heon SONG, Yongin-si (KR); Il Ha SONG, Yongin-si (KR); Dae Yong YOON, Yongin-si (KR)

(21) Appl. No.: 18/615,919

(22) Filed: Mar. 25, 2024

(30) Foreign Application Priority Data
Sep. 18, 2023 (KR) 10-2023-0124161

(51) Int. Cl. H10K 59/80; H10K 50/15; H10K 50/16; H10K 50/17; H10K 50/18; H10K 50/822; H10K 85/30; H10K 85/60; H10K 102/00

(52) U.S. Cl. CPC H10K 59/879; H10K 50/15; H10K 50/16; H10K 50/171; H10K 50/181; H10K 50/822; H10K 85/342; H10K 85/615; H10K 85/622; H10K 85/636; H10K 85/654; H10K 85/6572; H10K 85/6574; H10K 2102/351

(57) ABSTRACT

A display device may include: a light-emitting-element layer disposed on a substrate, and including an anode electrode, a cathode electrode, a first sub-pixel including a first emission structure, a second sub-pixel including a second emission structure, and a third sub-pixel including a third emission structure; and a lens-array layer on the light-emitting-element layer, and including lenses including first, second, and third lenses provided to respectively overlap the first, second, and third emission structures. In the first sub-pixel, first base light provided from the first emission structure may pass through the first lens and be provided as first light. In the second sub-pixel, second base light provided from the second emission structure may pass through the second lens and be provided as second light. In the third sub-pixel, third base light provided from the third emission structure may pass through the third lens and be provided as third light.

### CROSS-REFERENCE TO RELATED APPLICATION

The present application claims priority to and the benefit of Korean Patent Application No. 10-2023-0124161, filed on Sep. 18, 2023, in the Korean Intellectual Property Office, the entire content of which is incorporated by reference herein.

### BACKGROUND

### 1. Field

Various embodiments of the present disclosure relate to a display device.

### 2. Description of Related Art

Recently, as interest in information display increases, research and development on display devices have been continuously conducted.

Organic light emitting diodes (OLEDs) are active emission display elements that not only feature a large viewing angle and excellent contrast but also can operate at low voltage. The OLEDs have advantages of being lightweight and thin, and having fast response time characteristics.

OLEDs may include a plurality of layers, and light emitted from the OLEDs may pass through the plurality of layers and be provided outward. For example, the display devices may include a lens array structure. When light passes through the lens array structure, a color-shift phenomenon may occur.

In the case where the color-shift phenomenon excessively occurs, there may be concerns about distortion of image information intended to be provided from the display devices.

### SUMMARY

An aspect of embodiments of the present disclosure is directed to a display device having excellent color quality.

An aspect of embodiments of the present disclosure is directed to a display device having enhanced light output efficiency and light emitting efficiency.

An aspect of embodiments of the present disclosure is directed to a display device in which light output information may be defined in suitable or desired color coordinates, so that the reliability of the light output information can be improved.

An embodiment of the present disclosure may provide a display device, including: a light-emitting-element layer on a substrate, and including an anode electrode, a cathode electrode, a first sub-pixel including a first emission structure, a second sub-pixel including a second emission structure, and a third sub-pixel including a third emission structure; and a lens-array layer on the light-emitting-element layer, and including lenses including a first lens provided to overlap the first emission structure in a plan view, a second lens provided to overlap the second emission structure in a plan view, and a third lens provided to overlap the third emission structure in a plan view. In the first sub-pixel, a first base light provided from the first emission structure may pass through the first lens and be provided as a first light. In the second sub-pixel, a second base light provided from the second emission structure may pass through the second lens and be provided as a second light. In the third sub-pixel, a third base light provided from the third emission structure may pass through the third lens and be provided as a third light. An x-coordinate value of the International Commission on Illumination (CIE) color coordinates of the first base light may be in a range from 0.680 to 0.695, an x-coordinate value of the CIE color coordinates of the second base light may be in a range from 0.250 to 0.295, and a y-coordinate value of the CIE color coordinates of the third base light may be in a range from 0.060 to 0.100. An x-coordinate value of the CIE color coordinates of the first light may be in a range from 0.670 to 0.685, an x-coordinate value of the CIE color coordinates of the second light may be in a range from 0.230 to 0.265, and a y-coordinate value of the CIE color coordinates of the third light may be in a range from 0.040 to 0.060.

In an embodiment, the first light may be red light. The second light may be green light. The third light may be blue light. The display device may include the first sub-pixel configured to provide the red light, the second sub-pixel configured to provide the green light, and the third sub-pixel configured to provide the blue light without including a color filter.

In an embodiment, each of the first emission structure, the second emission structure, and the third emission structure may include a hole transport part, an electron transport part, and an emission layer between the hole transport part and the electron transport part. The emission layer may include a first emission layer included in the first emission structure, a second emission layer included in the second emission structure, and a third emission layer included in the third emission structure. The emission element layer may further include a capping layer on the cathode electrode. The respective electron transport parts of the first emission structure, the second emission structure, and the third emission structure may include a same material. The hole transport part of the third emission structure may have a material at least partially different from the hole transport part of each of the first emission structure and the second emission structure.

In an embodiment, the capping layer may include a CPL material (Chemical Formula 1). The hole transport part may include one or more selected from the group consisting of m-MTDATA (Chemical Formula 2), NPB (Chemical Formula 3), TCTA (Chemical Formula 4), S-HTL1 (Chemical Formula 5), S-HTL2 (Chemical Formula 6), S-HTL3 (Chemical Formula 7), S-HTL4 (Chemical Formula 8), and NDP-9 (Chemical Formula 9). The first emission layer may include TPBI (Chemical Formula 10) as a host and includes Ir(dmppy-ph)2(tmd) (Chemical Formula 11) as a red dopant. The second emission layer may include TBTI as a host and includes Irppy3 (Chemical Formula 12) as a green dopant. The third emission layer may include a blue host (Chemical Formula 13) as a host and include a blue dopant (Chemical Formula 14). The electron transport part may include one or more selected from the group consisting of T2T (Chemical Formula 15), TPM-TAZ (Chemical Formula 16), LiQ (lithium quinolate) (Chemical Formula 17), and Yb.

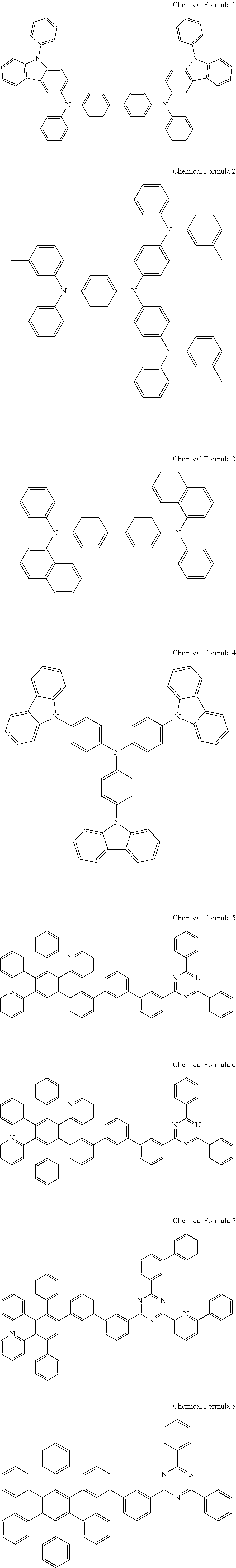

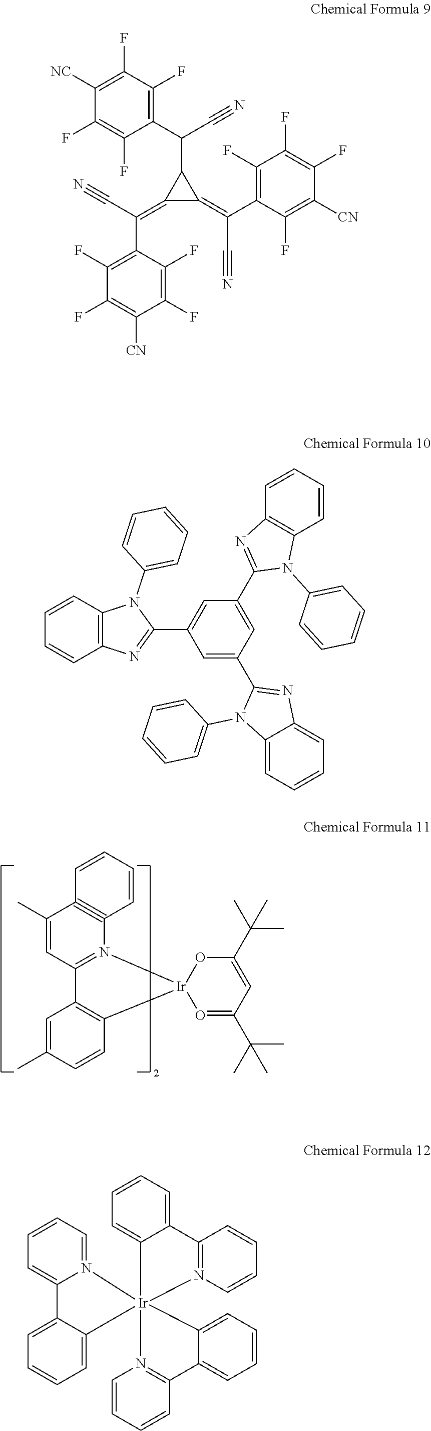

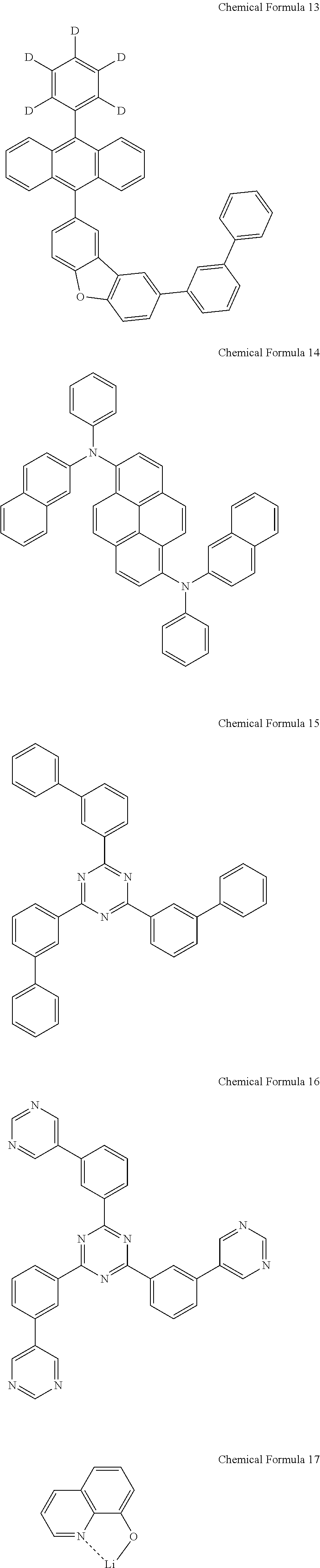

In an embodiment, the hole transport part of the first emission structure may include a first hole injection layer, a first hole transport layer on the first hole injection layer, and a first electron blocking layer on the first hole transport layer. The hole transport part of the second emission structure may include a second hole injection layer, a second hole transport layer on the second hole injection layer, and a second electron blocking layer on the second hole transport layer. The hole transport part of the third emission structure may include a third hole injection layer, a third hole transport layer on the third hole injection layer, and a third electron blocking layer on the third hole transport layer. The electron transport part of each of the first emission structure, the second emission structure, and the third emission structure may include: a hole blocking layer, an electron transport layer on the hole blocking layer, and an electron injection layer on the electron transport layer.

In an embodiment, each of the first hole injection layer and the second hole injection layer may have a thickness in a range from 25 Å to 75 Å. Each of the first hole transport layer and the second hole transport layer may have a thickness in a range from 800 Å to 1500 Å. The first electron blocking layer may have a thickness in a range from 700 Å to 900 Å. The second electron blocking layer may have a thickness in a range from 350 Å to 600 Å. The third hole injection layer may have a thickness in a range from 25 Å to 75 Å. The third hole transport layer may have a thickness in a range from 1150 Å to 1300 Å. The third electron blocking layer may have a thickness in a range from 25 Å to 75 Å.

In an embodiment, the first emission layer may have a thickness in a range from 320 Å to 520 Å. The second emission layer may have a thickness in a range from 280 Å to 480 Å. The third emission layer may have a thickness in a range from 150 Å to 250 Å.

In an embodiment, in each of the first emission structure, the second emission structure, and the third emission structure, the hole blocking layer may have a thickness in a range from 25 Å to 75 Å, the electron transport layer may have a thickness in a range from 250 Å to 370 Å, and the electron injection layer may have a thickness in a range from 7 Å to 13 Å.

In an embodiment, the display device may further include an overcoat layer on the lens-array layer. The lenses may have a refractive index higher than the overcoat layer.

In an embodiment, the lenses may include one or more selected from the group consisting of acryl resin, epoxy resin, phenolic resin, polyamide resin, polyimide resin, polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polycarbonate (PC), cellulose triacetate (CAT), and cellulose acetate propionate (CAP).

In an embodiment, each of the lenses may include a side surface. The side surface may form an included angle in a range from 50° to 70° with respect to a base on which the lens array layer is provided.

In an embodiment, each of the lenses may have a semi-circular cross-section.

In an embodiment, each of the lenses may have a trapezoidal cross-section.

In an embodiment, each of the lenses may include a lower lens part and an upper lens part on the lower lens part. The lower lens part may have a first trapezoidal cross-section. The upper lens part may have a second trapezoidal cross-section that is not in a similar geometric relationship with the first trapezoidal cross-section.

In an embodiment, each of the lenses may include a lower lens part and an upper lens part on the lower lens part. The lower lens part may have a trapezoidal cross-section. The upper lens part may have a semi-circular cross-section.

In an embodiment, the cathode electrode may have a thickness in a range from 70 Å to 140 Å.

In an embodiment, the cathode electrode may include at least one selected from silver (Ag), magnesium (Mg), and a compound thereof.

In an embodiment, the substrate may include a silicon wafer substrate.

An embodiment of the present disclosure may provide a display device, including: a light-emitting-element layer on a substrate, and including an anode electrode, a cathode electrode, a first sub-pixel including a first emission structure, a second sub-pixel including a second emission structure, and a third sub-pixel including a third emission structure; and a lens-array layer on the light-emitting-element layer, and including lenses including a first lens provided to overlap the first emission structure in a plan view, a second lens provided to overlap the second emission structure in a plan view, and a third lens provided to overlap the third emission structure in a plan view. Each of the lenses may include a lower lens part and an upper lens part on the lower lens part. The lower lens part may have a trapezoidal cross-section. The upper lens part may have a semi-circular cross-section.

An embodiment of the present disclosure may provide a display device, including: a light-emitting-element layer on a substrate, and including an anode electrode, a cathode electrode, a first sub-pixel including a first emission structure, a second sub-pixel including a second emission structure, and a third sub-pixel including a third emission structure; and a lens-array layer on the light-emitting-element layer, and including lenses including a first lens provided to overlap the first emission structure in a plan view, a second lens provided to overlap the second emission structure in a plan view, and a third lens provided to overlap the third emission structure in a plan view. The display device may include the first sub-pixel, the second sub-pixel, and the third sub-pixel without including a color filter. The cathode electrode may include a same material in each of the first emission structure, the second emission structure, and the third emission structure, and may have a thickness in a range from 70 Å to 140 Å.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a schematic plan view illustrating a display device in accordance with an embodiment.

FIG. 2 is a schematic exploded perspective view illustrating a portion of the display device in accordance with an embodiment.

FIG. 3 is a plan view illustrating an embodiment of any one of the pixels of FIG. 2.

FIG. 4 is a plan view illustrating an embodiment of any one of the pixels of FIG. 2.

FIG. 5 is a plan view illustrating an embodiment of any one of the pixels of FIG. 2.

FIG. 6 is a cross-sectional view taken along line I-I′ of FIG. 3.

FIG. 7 is a schematic cross-sectional view illustrating a light-emitting-element layer in accordance with an embodiment.

FIG. 8 is a schematic enlarged view of area EA1 of FIG. 6.

FIGS. 9 to 12 are schematic cross-sectional views each illustrating a lens-array layer in accordance with an embodiment.

FIG. 13 is a block diagram illustrating an embodiment of a display system.

FIG. 14 is a perspective diagram illustrating an application example of the display system of FIG. 13.

FIG. 15 is a diagram illustrating a head mounted display device of FIG. 14 that is worn on a user.

### DETAILED DESCRIPTION

Hereinafter, an embodiment of the present disclosure will be described in more detail with reference to the attached drawings. In the following description, only parts useful or required for understanding of operations in accordance with the present disclosure will be described, and explanation of the other parts may be omitted to make the present disclosure clearer. Accordingly, the subject matter of the present disclosure is not limited to the embodiments set forth herein but may be embodied in other types or forms. Rather, these embodiments are provided so that the present disclosure will be thorough and complete, and will fully convey the technical spirit of the disclosure to those skilled in the art.

It will be understood that when an element is referred to as being “coupled” or “connected” to another element, it can be directly coupled or connected to the other element or intervening elements may be present therebetween. The terminology used herein is for the purpose of describing particular embodiments only and is not intended to be limiting. In the specification, when an element is referred to as “comprising” or “including” a component, it does not preclude another component but may further include other components unless the context clearly indicates otherwise. “at least one of X, Y, and Z” and “at least one selected from the group consisting of X, Y, and Z” may be construed as X only, Y only, Z only, or any combination of two or more of X, Y, and Z (for instance, XYZ, XYY, YZ, and ZZ). As used herein, the term “and/or” can include any and all combinations of one or more of the associated listed items.

Although the terms “first,” “second,” etc. may be used herein to describe various types (or kinds) of elements, these elements should not be limited by these terms. These terms are used to distinguish one element from another element. Thus, a first element discussed below could be termed a second element without departing from the spirit or scope of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element or feature's relationship to another element(s) or feature(s), as illustrated in the drawings. Spatially relative terms are intended to encompass different orientations of an apparatus in use, operation, and/or manufacture in addition to the orientation depicted in the drawings. For example, if the device in the drawings is turned upside down, elements described as “below” or “beneath” other elements or features would then be oriented “above” the other elements or features. Thus, the term “below” can encompass both an orientation of above and below. Furthermore, the device may be otherwise oriented (e.g., rotated 90 degrees or at other orientations), and, as such, the spatially relative descriptors used herein interpreted accordingly.

Various embodiments will be described with reference to the drawings, which may illustrate idealized embodiments. As such, variations from the shapes of the illustrations as a result, for example, of manufacturing techniques and/or tolerances, may be expected. Therefore, embodiments disclosed herein should not be construed as limited to the particular illustrated shapes of regions, but are to include deviations in shapes that result from, for instance, manufacturing. As such, the shapes illustrated in the drawings may not illustrate the actual shapes of regions of a device, and, as such, are not intended to be limiting.

Various embodiments of the present disclosure relate to a display device. Hereinafter, a display device in accordance with an embodiment will be described with reference to the attached drawings.

### 1. Display Device

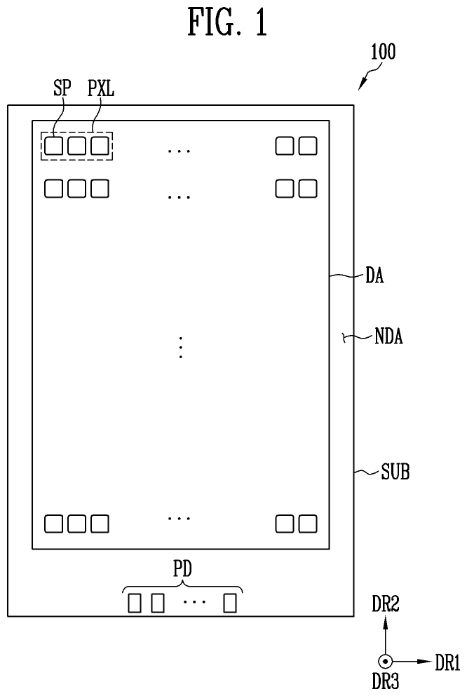

FIG. 1 is a schematic plan view illustrating a display device 100 in accordance with an embodiment.

Referring to FIG. 1, the display device 100 in accordance with an embodiment is configured to emit light.

The display device 100 may include a display area DA and a non-display area NDA. The display device 100 may display an image through the display area DA. The non-display area NDA may be provided around the display area DA.

The display device 100 may include a substrate SUB, sub-pixels SP, and pads PD.

In the case where the display device 100 is used as a display screen for a head mounted display (HMD), a virtual reality (VR) device, a mixed reality (MR) device, an augmented reality (AR) device, and/or the like, the display device 100 may be positioned very close to the eyes of the user. In this case, relatively high-density sub-pixels SP may be useful or required. To increase the pixel density of the sub-pixels SP, the substrate SUB may be provided as a silicon substrate. The sub-pixels SP and/or other elements of the display device 100 may be provided on the substrate SUB, which is a silicon substrate. The display device 100 including the substrate SUB that is a silicon substrate may be referred to as an OLED on Silicon (OLEDoS) display device.

The sub-pixels SP may be provided in the display area DA on the substrate SUB. The sub-pixels SP may be arranged in the form of a matrix along a first direction DR1 and a second direction DR2 intersecting with the first direction DR1. However, embodiments are not limited to the aforementioned example. For example, the sub-pixels SP may be arranged in a zigzag pattern in the first direction DR1 and the second direction DR2. For example, the sub-pixels SP may be arranged in the form of a PENTILE® arrangement structure (e.g., an RGBG matrix, RGBG structure, or RGBG matrix structure), but the present disclosure is not limited thereto. PENTILE® is a duly registered trademark of Samsung Display Co., Ltd. The first direction DR1 may refer to a row direction, and the second direction DR2 may refer to a column direction.

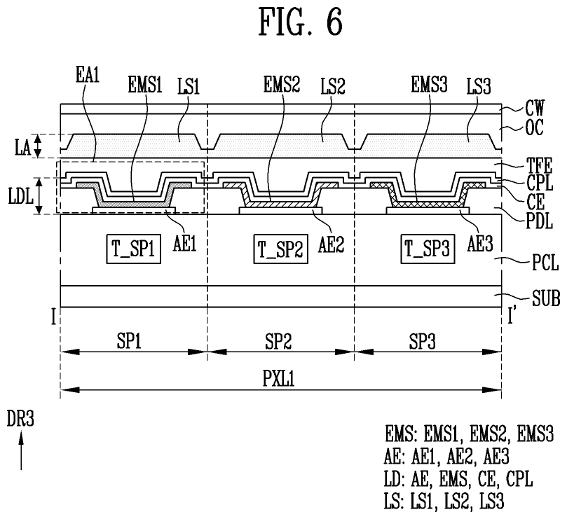

Each of the sub-pixels SP may include at least one light emitting element LD (refer to FIG. 6) configured to generate light. Accordingly, each of the sub-pixels SP may generate light in a set or specific color such as red, green, blue, cyan, magenta, or yellow. Two or more sub-pixels SP among the sub-pixels SP may form one pixel PXL. For example, as illustrated in FIG. 1, three sub-pixels SP may form one pixel PXL.

Hereinafter, descriptions will be provided based on an embodiment where the sub-pixels SP include a first sub-pixel SP1 configured to provide light of a first color (e.g., red), a second sub-pixel SP2 configured to provide light of a second color (e.g., green), and a third sub-pixel SP3 configured to provide light of a third color (e.g., blue), but the present disclosure is not limited thereto.

In an embodiment, the first sub-pixel SP1 may provide light in a wavelength band in a range from 600 nm to 750 nm as a red pixel. The second sub-pixel SP2 may provide light in a wavelength band in a range from 480 nm to 560 nm as a green pixel. The third sub-pixel SP3 may provide light in a wavelength band in a range from 370 nm to 460 nm as a blue pixel.

Components for controlling the sub-pixels SP may be in the non-display area NDA on the substrate SUB. For example, lines connected to the sub-pixels SP (e.g., gate lines and data lines for driving the sub-pixels SP) may be in the non-display area NDA. Furthermore, a gate driver, a data driver, a voltage generator, a controller, a temperature sensor, and/or the like may be integrated in the non-display area NDA of the display device 100 to acquire driving signals to be supplied to the sub-pixels SP. However, the present disclosure is not limited to the aforementioned example.

The pads PD may be in the non-display area NDA on the substrate SUB. The pads PD may be electrically connected to the sub-pixels SP through the lines. For example, the pads PD may be connected to the sub-pixels SP through the data lines.

The pads PD may interface the components in the display area DA and the non-display area NDA with other components of the display device 100. In embodiments, voltages and signals useful or required for the operation of the components included in the display device 100 may be provided from a driver integrated circuit through the pads PD. For example, the data lines may be electrically connected to the driver integrated circuit through the pads PD. For example, the power voltages for driving the sub-pixels SP may be received from the driver integrated circuit through the pads PD. For example, a gate control signal for controlling the gate driver may be transmitted from the driver integrated circuit to the gate driver through the pads PD.

In embodiments, a circuit board may be electrically connected to the pads PD by a conductive adhesive component (e.g., an electrically conductive adhesive component) such as an anisotropic conductive film. Here, the circuit board may be a flexible circuit board or flexible film that is made of a flexible material. The driver integrated circuit may be mounted on the circuit board and be electrically connected to the pads PD.

In embodiments, the display area DA may have various suitable shapes. The display area DA may have a closed-loop shape, including linear and/or curved sides. For example, the display area DA may have shapes such as polygons, circles, semicircles, ellipses, and/or the like.

In embodiments, the display device 100 may have a planar display surface. In embodiments, the display device 100 may have a display surface that is at least partially rounded. In embodiments, the display device 100 may be bendable, foldable, and/or rollable. In the aforementioned cases, the display device 100 and/or the substrate SUB may include materials having flexible properties.

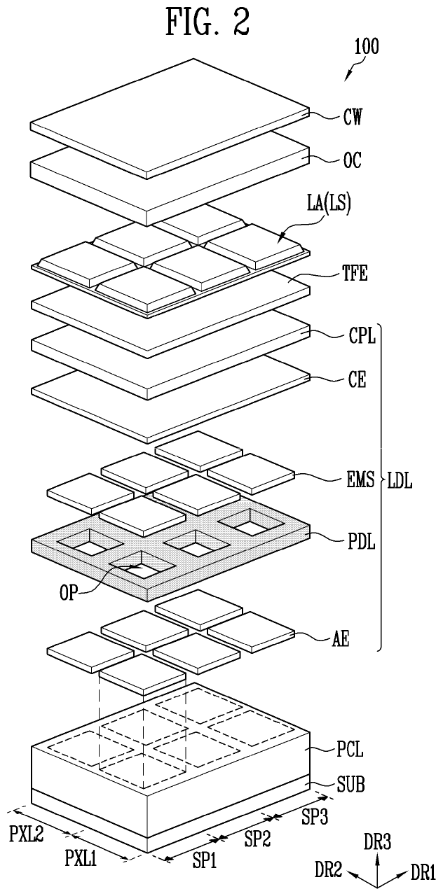

FIG. 2 is a schematic exploded perspective view illustrating a portion of the display device 100 in accordance with an embodiment. In FIG. 2, for the sake of clear and concise explanation, there is schematically illustrated a portion of the display device 100 corresponding to two pixels PXL1 and PXL2 among the pixels PXL of FIG. 1. The portion of the display device 100 corresponding to the remaining pixels PXL may also be configured in the same manner.

Referring to FIGS. 1 and 2, each of the first pixel PXL1 and the second pixel PXL2 may include a first sub-pixel SP1, a second sub-pixel SP2, and a third sub-pixel SP3. However, embodiments are not limited to the aforementioned example. In an embodiment, each of the first pixel PXL1 and the second pixel PXL2 may include four sub-pixels, or may include two sub-pixels.

In FIG. 2 the first sub-pixel SP1, the second sub-pixel SP2, and the third sub-pixel SP3 are illustrated as having rectangular shapes and the same size when viewed in a third direction DR3 intersecting with the first and second directions DR1 and DR2. However, embodiments are not limited to the aforementioned example. Each of the first sub-pixel SP1, the second sub-pixel SP2, and the third sub-pixel SP3 may be changed to have various suitable shapes.

The display device 100 may include the substrate SUB, a pixel-circuit layer PCL, a light-emitting-element layer LDL, an encapsulation layer TFE, a lens-array layer LA, an overcoat layer OC, and a cover window CW.

In embodiments, the substrate SUB may include a silicon wafer substrate formed through a semiconductor process. The substrate SUB may include semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOl) layer, and/or the like. In embodiments, the substrate SUB may include a glass substrate. In embodiments, the substrate SUB may include a polyimide (PI) substrate.

The pixel-circuit layer PCL may be on the substrate SUB. The substrate SUB and/or the pixel-circuit layer PCL may include insulating layers (e.g., electrically insulating layers), and conductive patterns (e.g., electrically conductive patterns) between the insulating layers. The conductive patterns of the pixel-circuit layer PCL may function as at least some of the circuit elements, lines, and/or the like. The conductive patterns may include copper, but are not limited thereto.

The circuit elements may include a sub-pixel circuit of each of the first sub-pixel SP1, the second sub-pixel SP2, and the third sub-pixel SP3. The sub-pixel circuit may include transistors and one capacitor or two or more capacitors. Each transistor may include a semiconductor portion including a source area, a drain area, and a channel area, and a gate electrode overlapping the semiconductor portion. In embodiments, in the case where the substrate SUB is formed of a silicon substrate, the semiconductor portion may be included in the substrate SUB, and the gate electrode may be included in the pixel-circuit layer PCL as a conductive pattern (e.g., an electrically conductive pattern) of the pixel-circuit layer PCL. In an embodiment, in the case where the substrate SUB is formed of a glass substrate and/or a PI substrate, the semiconductor portion and the gate electrode may be included in the pixel-circuit layer PCL. Each capacitor may include electrodes spaced apart from each other. For example, each capacitor may include electrodes spaced apart from each other on a plane defined in the first and second directions DR1 and DR2. For example, each capacitor may include electrodes spaced apart from each other in the third direction DR3 with an insulating layer (e.g., an electrically insulating layer) therebetween.

The lines of the pixel-circuit layer PCL may include signal lines connected to each of the first sub-pixel SP1, the second sub-pixel SP2, and the third sub-pixel SP3, for example, a gate line, an emission control line, and a data line. The lines may include a first power line that is electrically connected to the sub-pixel circuit to supply a high-potential voltage, and a second power line electrically connected to the light emitting element LD to supply a low-potential voltage.

The light-emitting-element layer LDL may include anode electrodes AE, a pixel defining layer PDL, an emission structure EMS, a cathode electrode CE, and a capping layer CPL.

The anode electrodes AE may be on the pixel-circuit layer PCL. The anode electrodes AE may electrically contact circuit elements of the pixel-circuit layer PCL.

The pixel defining layer PDL may be on the anode electrodes AE. The pixel defining layer PDL may include openings OP that expose respective portions of the anode electrodes AE. The openings OP in the pixel defining layer PDL may be understood as respective emission areas corresponding to the first sub-pixel SP1, the second sub-pixel SP2, and third sub-pixel SP3.

In embodiments, the pixel defining layer PDL may include an inorganic material. In this case, the pixel defining layer PDL may include a plurality of inorganic layers stacked on top of one another. For example, the pixel defining layer PDL may include silicon oxide (SiOx) and silicon nitride (SiNx). In an embodiment, the pixel defining layer PDL may include an organic material. However, the material of the pixel defining layer PDL is not limited thereto.

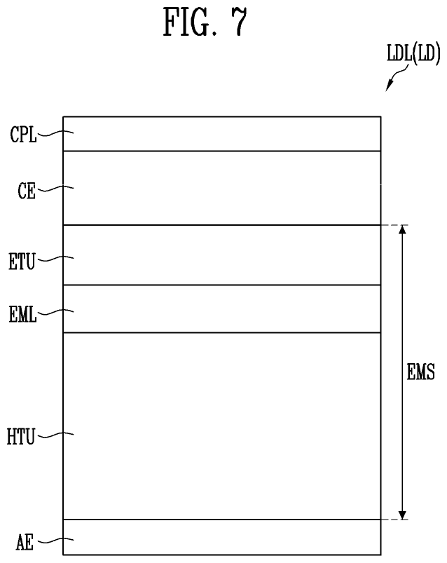

The emission structure EMS may be on the anode electrodes AE exposed through the openings OP in the pixel defining layer PDL. The emission structure EMS may include an emission layer EML (refer to FIG. 7) configured to generate light, an electron transport part ETU (refer to FIG. 7) configured to transport electrons, and a hole transport part HTU (refer to FIG. 7) configured to transport holes.

In embodiments, the emission structure EMS may fill the openings OP in the pixel defining layer PDL. A portion of the emission structure EMS may be on the pixel defining layer PDL.

The emission structure EMS may include a first emission structure EMS1 (refer to FIG. 6) included in the first sub-pixel SP1 and configured to emit light of a first base color, a second emission structure EMS2 (refer to FIG. 6) included in the second sub-pixel SP2 and configured to emit light of a second base color, and a third emission structure EMS3 (refer to FIG. 6) included in the third sub-pixel SP3 and configured to emit light of a third base color.

The cathode electrode CE may be on the emission structure EMS. The cathode electrode CE may extend over the first sub-pixel SP1, the second sub-pixel SP2, and the third sub-pixel SP3. As such, the cathode electrode CE may be provided as a common electrode for the first sub-pixel SP1, the second sub-pixel SP2, and the third sub-pixel SP3.

The cathode electrode CE may be a thin-film metal layer having a thickness allowing light emitted from the emission structure EMS to pass therethrough. The cathode electrode CE may be made of a metal material having a relatively small thickness, and/or a transparent conductive material. In embodiments, the cathode electrode CE may include at least one of various suitable transparent conductive materials including indium tin oxide, indium zinc oxide, indium tin zinc oxide, aluminum zinc oxide, gallium zinc oxide, zinc tin oxide, and/or gallium tin oxide. In embodiments, the cathode electrode CE may include at least one selected from silver (Ag), magnesium (Mg), and a compound thereof. However, the material of the cathode electrode CE is not limited thereto.

Any one selected from the anode electrodes AE, a portion of the emission structure EMS that overlap the any one of the anode electrodes AE, and a portion of the cathode electrode CE that overlaps the portion of the emission structure EMS can be understood as constituting one light emitting element LD. In embodiments, each of the light emitting elements LD of the first sub-pixel SP1, the second sub-pixel SP2, and the third sub-pixel SP3 may include one anode electrode AE, a portion of the emission structure EMS that overlaps the one anode electrode AE, and a portion of the cathode electrode CE that overlaps the portion of the emission structure EMS. In each of the first sub-pixel SP1, the second sub-pixel SP2, and the third sub-pixel SP3, holes injected from the anode electrode AE and electrons injected from the cathode electrode CE are transported into the emission structure EMS, thus forming excitons. When the excitons make a transition from an excited state to a ground state, light can be generated. The luminance of light may be determined based on the amount of current flowing through the emission structure EMS. Depending on the configuration of the emission structure EMS, the wavelength range of light to be generated may be determined.

The capping layer CPL may be on the cathode electrode CE. The capping layer CPL may cover the cathode electrode CE. The capping layer CPL may extend over the first sub-pixel SP1, the second sub-pixel SP2, and the third sub-pixel SP3.

The capping layer CPL may include an organic material and/or an inorganic material having a relatively high refractive index. For example, the capping layer CPL may reflect at least some of light provided from the light emitting element LD to form a light recycling structure, thereby improving light output efficiency of the light emitting element LD. In an embodiment, the capping layer CPL may include CPL material (represented by Chemical Formula 1). However, the present disclosure is not limited to the aforementioned example.

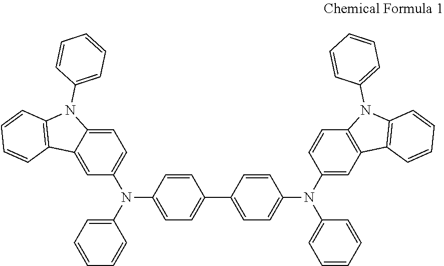 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

The encapsulation layer TFE may be on the capping layer CPL. The encapsulation layer TFE may cover the light-emitting-element layer LDL and/or the pixel-circuit layer PCL. The encapsulation layer TFE may be configured to prevent or reduce penetration of oxygen and/or water and/or the like into the light-emitting-element layer LDL. In embodiments, the encapsulation layer TFE may include a structure formed by alternately stacking one or more inorganic layers and one or more organic layers. For example, the inorganic layer may include silicon nitride, silicon oxide, silicon oxynitride (SiOxNy), and/or the like. For example, the organic layer may include an organic insulating material (e.g., an organic electrically insulating material) such as polyacrylates resin, epoxy resin, phenolic resin, polyamides resin, polyimides resin, unsaturated polyesters resin, polyphenylenes resin, polyphenylene sulfides resin, and/or benzocyclobutene (BCB). However, the materials of the organic layer and the inorganic layer of the encapsulation layer TFE are not limited to the aforementioned examples.

The encapsulation layer TFE may further include a thin film, including aluminum oxide (AlOx), to enhance the encapsulation efficiency of the encapsulation layer TFE. The thin film including aluminum oxide may be on an upper surface of the encapsulation layer TFE that faces the lens-array layer LA and/or under a lower surface of the encapsulation layer TFE that faces the light-emitting-element layer LDL.

The thin film including aluminum oxide may be formed through an atomic layer deposition (ALD) method. However, embodiments are not limited to the aforementioned example. The encapsulation layer TFE may further include a thin film formed of at least one of various suitable materials suitable for enhancing the encapsulation efficiency.

The lens-array layer LA may be on the encapsulation layer TFE. The lens-array layer LA may include lenses LS that respectively correspond to the first sub-pixel SP1, the second sub-pixel SP2, and the third sub-pixel SP3. Each of the lenses LS may output and direct light emitted from the emission structure EMS along an intended path, thus enhancing the light output efficiency. The lenses LS may have a relatively high refractive index. For example, the lenses LS may have a higher refractive index than the overcoat layer OC.

In embodiments, the lenses LS may include an organic material. In embodiments, the lenses LS may include one or more selected from the group consisting of acryl resin, epoxy resin, phenolic resin, polyamide resin, polyimide resin, polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), and cellulose acetate propionate (CAP). However, the present disclosure is not limited to a specific example.

In embodiments, with respect to the openings OP of the pixel defining layer PDL, at least some of the lenses LS of the lens-array layer LA may be shifted in a direction parallel (e.g., substantially parallel) to the plane defined in the first and second directions DR1 and DR2. For example, in a central area of the display area DA, the center of each of the lenses LS may be aligned and/or overlapped with the center of the corresponding opening OP of the pixel defining layer PDL in the third direction DR3. For instance, in the central area of the display area DA, each opening OP of the pixel defining layer PDL may completely overlap the corresponding lens LS of the lens-array layer LA. In an area of the display area DA that is adjacent to the non-display area NDA, the center of the lens LS may be shifted in a plane direction from the center of the corresponding opening OP of the pixel defining layer PDL when viewed in the third direction DR3. For example, in the area of the display area DA that is adjacent to the non-display area NDA, each opening OP of the pixel defining layer PDL may partially overlap the corresponding lens LS of the lens-array layer LA. Accordingly, light emitted from the emission structure EMS in the central portion of the display area DA may be efficiently outputted in the normal direction of the display surface. Light emitted from the emission structure EMS around the perimeter of the display area DA may be efficiently outputted in a direction inclined at an angle with respect to the normal direction of the display surface.

The overcoat layer OC may be on the lens-array layer LA. The overcoat layer OC may cover the lens-array layer LA, the encapsulation layer TFE, the emission structure EMS, and/or the pixel-circuit layer PCL. The overcoat layer OC may include various suitable materials suitable for protecting underlying layers from foreign substances such as dust, water, and/or the like. For example, the overcoat layer OC may include at least one of an inorganic insulating layer (e.g., an inorganic electrically insulating layer) and an organic insulating layer (e.g., an organic electrically insulating layer). For example, the overcoat layer OC may include epoxy, but it is not limited thereto. The overcoat layer OC may have a lower refractive index than the lens-array layer LA.

The cover window CW may be on the overcoat layer OC. The cover window CW may be configured to protect underlying layers. The cover window CW may have a higher refractive index than the overcoat layer OC. The cover window CW may include glass, but embodiments are not limited thereto. For example, the cover window CW may be an encapsulation glass layer configured to protect components disposed thereunder. In an embodiment, the cover window CW may be omitted.

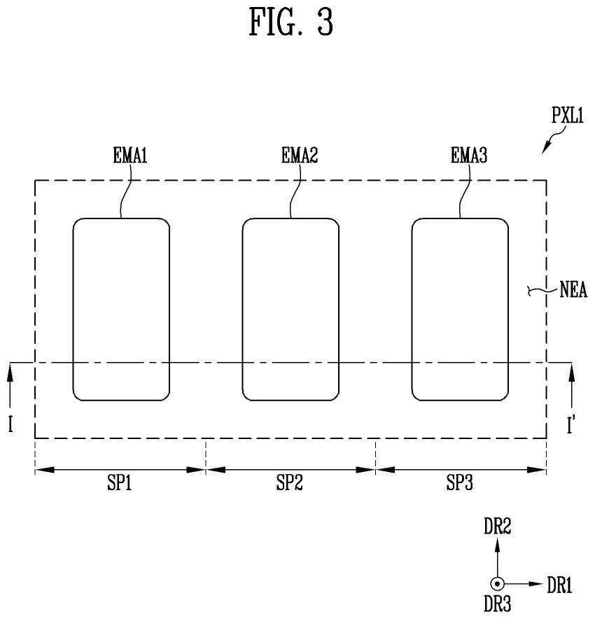

FIG. 3 is a plan view illustrating an embodiment of any one of the pixels of FIG. 2. In FIG. 3, for the sake of clear and concise explanation, the first pixel PXL1 of the first pixel PXL1 and the second pixel PXL2 of FIG. 2 are schematically depicted. The other pixels may be configured in the same manner as the first pixel PXL1.

Referring to FIGS. 2 and 3, the first pixel PXL1 may include a first sub-pixel SP1, a second sub-pixel SP2, and a third sub-pixel SP3 that are arranged in the first direction DR1.

The first sub-pixel SP1 may include a first emission area EMA1 and a non-emission area NEA provided around the first emission area EMA1. The second sub-pixel SP2 may include a second emission area EMA2 and a non-emission area NEA provided around the second emission area EMA2. The third sub-pixel SP3 may include a third emission area EMA3 and a non-emission area NEA provided around the third emission area EMA3.

The first emission area EMA1 may be an area where light is emitted from a portion of the emission structure EMS (e.g., from the first emission structure EMS1) that corresponds to the first sub-pixel SP1. The second emission area EMA2 may be an area where light is emitted from a portion of the emission structure EMS (e.g., from the second emission structure EMS2) that corresponds to the second sub-pixel SP2. The third emission area EMA3 may be an area where light is emitted from a portion of the emission structure EMS (e.g., from the third emission structure EMS3) that corresponds to the third sub-pixel SP3. As described with reference to FIG. 2, each emission area may be understood as the opening OP of the pixel defining layer PDL that corresponds to each of the first sub-pixel SP1, the second sub-pixel SP2, and the third sub-pixel SP3.

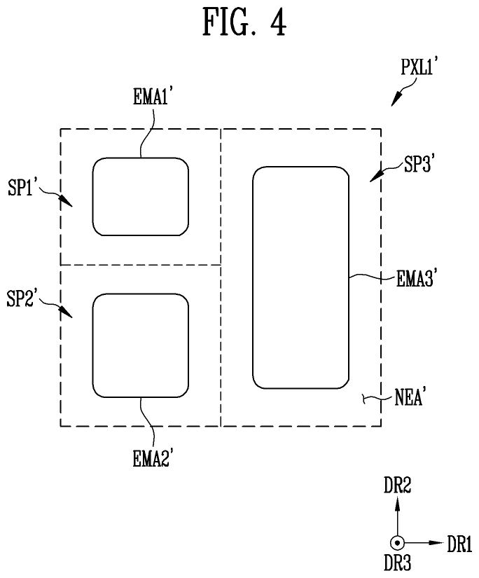

FIG. 4 is a plan view illustrating an embodiment of any one of the pixels of FIG. 2.

Referring to FIG. 4, a first pixel PXL1′ may include first to third sub-pixels SP1′ to SP3′.

The first sub-pixel SP1′ may include a first emission area EMA1′ and a non-emission area NEA′ provided around the first emission area EMA1′. The second sub-pixel SP2′ may include a second emission area EMA2′ and a non-emission area NEA′ provided around the second emission area EMA2′. The third sub-pixel SP3′ may include a third emission area EMA3′ and a non-emission area NEA′ provided around the third emission area EMA3′.

The first sub-pixel SP1′ and the second sub-pixel SP2′ may be provided in the second direction DR2. The third sub-pixel SP3′ may be provided in the first direction with respect to each of the first and second sub-pixels SP1′ and SP2′.

The second sub-pixel SP2′ may have a larger surface area than the first sub-pixel SP1′. The third sub-pixel SP3′ may have a larger surface area than the second sub-pixel SP2′. Therefore, the second emission area EMA2′ may have a larger surface area than the first emission area EMA1′. The third emission area EMA3′ may have a larger surface area than the second emission area EMA2′. However, embodiments are not limited to the aforementioned example. For example, the first and second sub-pixels SP1′ and SP2′ may have substantially the same surface area. The third sub-pixel SP3′ may have a larger surface area than each of the first and second sub-pixels SP1′ and SP2′. As such, the surface areas of the first to third sub-pixels SP1′ to SP3′ may be changed in various suitable ways depending on embodiments.

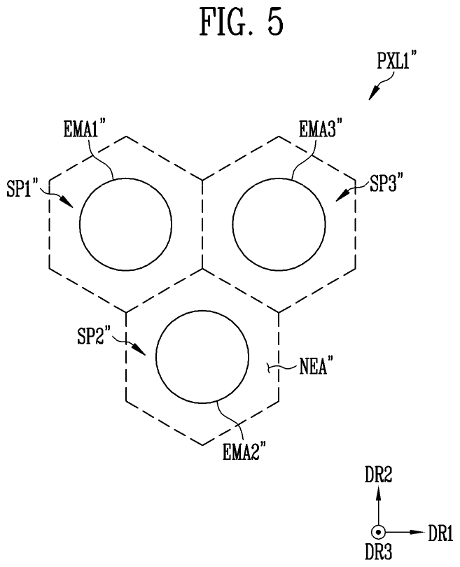

FIG. 5 is a plan view illustrating an embodiment of any one of the pixels of FIG. 2.

Referring to FIG. 5, a first sub-pixel SP1″ may include a first emission area EMA1″ and a non-emission area NEA″ provided around the first emission area EMA1″. A second sub-pixel SP2″ may include a second emission area EMA2″ and a non-emission area NEA″ provided around the second emission area EMA2″. The third sub-pixel SP3″ may include a third emission area EMA3″ and a non-emission area NEA″ provided around the third emission area EMA3″.

Each of the first to third sub-pixels SP1″ to SP3″ may have a polygonal shape in the third direction DR3. For example, the shapes of the first to third sub-pixels SP1″ to SP3″ may be hexagonal, as illustrated in FIG. 5.

Each of the first to third emission areas EMA1″ to EMA3″ may have a circular shape in the third direction DR3. However, embodiments are not limited to the aforementioned example. For example, each of the first to third emission areas EMA1″ to EMA3″ may have a polygonal shape.

The first and third sub-pixels SP1″ and SP3″ may be provided in the first direction DR1. The second sub-pixel SP2″ may be provided in a direction (or a diagonal direction) inclined at an acute angle based on the second direction DR2 with respect to the first sub-pixel SP1″.

The arrangements of the sub-pixels illustrated in FIGS. 3 to 5 are illustrative, and embodiments are not limited thereto. Each pixel PXL may include two or more sub-pixels SP. The sub-pixels SP may be provided in various suitable ways. Each of the sub-pixels SP may have various suitable shapes, and each of the emission areas EMA1, EMA2, and EMA3 of the sub-pixels SP may have various suitable shapes.

FIG. 6 is a cross-sectional view taken along line I-I′ of FIG. 3. FIG. 6 is a schematic cross-sectional view illustrating the display device in accordance with an embodiment. Description overlapping that of the embodiments described above may be simplified, or may not be repeated.

Referring to FIG. 6, the display device 100 may include the substrate SUB, and the pixel-circuit layer PCL, the light-emitting-element layer LDL, the encapsulation layer TFE, the lens-array layer LA, the overcoat layer OC, and the cover window CW that are on the substrate SUB.

The pixel-circuit layer PCL may include respective circuit elements of the first to third sub-pixels SP1 to SP3. For example, the substrate SUB and the pixel-circuit layer PCL may include a transistor T_SP1 of the first sub-pixel SP1, a transistor T_SP2 of the second sub-pixel SP2, and a transistor T_SP3 of the third sub-pixel SP3.

In an embodiment, the pixel-circuit layer PCL may further include a via layer and/or a planarization layer, and may further include reflective electrodes under the light emitting element layer LDL.

With reference to FIG. 7, the light emitting element LD included in the light-emitting-element layer LDL will be further described. FIG. 7 is a schematic cross-sectional view illustrating the light-emitting-element layer LDL in accordance with an embodiment.

In an embodiment, the respective light emitting elements LD of each of the sub-pixels SP may emit light of different colors.

The emission structures EMS (e.g., the emission layers EML) may be configured to emit light of different colors from the respective sub-pixels SP, thus allowing the display device 100 to provide a full-color image. In this case, the sub-pixels SP may be further suitable for implementing a display device 100 having ultra-high resolution. Furthermore, there may be no need to essentially provide a color filter allowing light of one color to pass therethrough, thus leading to a reduction in the number of layers utilized or required for the display device 100. However, the present disclosure is not limited to the aforementioned example. In an embodiment, the display device 100 may further include a color filter.

The light emitting element LD (or the light-emitting-element layer LDL) may include an anode electrode AE, an emission structure EMS, a cathode electrode CE, and a capping layer CPL.

The anode electrode AE may include various suitable conductive materials (e.g., electrically conductive materials). For example, the anode electrodes AE may include a transparent conductive material. For example, the anode electrodes AE may include at least one of transparent conductive materials such as indium tin oxide (ITO), indium zinc oxide (IZO), zinc oxide (ZnOx), indium gallium zinc oxide (IGZO), and/or indium tin zinc oxide (ITZO). However, the present disclosure is not limited to the foregoing. The anode electrodes AE may include opaque conductive material capable of reflecting light. For example, the anode electrodes AE may include one or more selected from the group consisting of titanium nitride (TiN), silver (Ag), and aluminum (Al).

The anode electrode AE may be on the pixel-circuit layer PCL. In an embodiment, the anode electrode AE may form a lower electrode of the light emitting element LD.

The anode electrode AE may include a first anode electrode AE1 included in the first sub-pixel SP1 and electrically connected to the first emission structure EMS1, a second anode electrode AE2 included in the second sub-pixel SP2 and electrically connected to the second emission structure EMS2, and a third anode electrode AE3 included in the third sub-pixel SP3 and electrically connected to the third emission structure EMS3.

In an embodiment, the first to third anode electrodes AE1 to AE3 may respectively include conductive layers (e.g., electrically conductive layers) provided in the same layer. For example, the first to third anode electrodes AE1 to AE3 may respectively include conductive layers (e.g., electrically conductive layers) including the same material. Any one or more of the first to third anode electrodes AE1 to AE3 may further include an additional conductive layer (e.g., an additional electrically conductive layer).

For example, the first anode electrode AE1 may include a conductive layer (e.g., an electrically conductive layer) structure including a first conductive layer (e.g., a first electrically conductive layer) formed by stacking aluminum (Al) and titanium nitride (TiN) and a second conductive layer (e.g., a second electrically conductive layer) formed by stacking indium tin oxide and silver (e.g., a structure in which ITO/Ag is on Al/TiN). Each of the second anode electrode AE2 and the third anode electrode AE3 may include a conductive structure (e.g., an electrically conductive structure) including a first conductive layer (e.g., a first electrically conductive layer) formed by stacking aluminum (Al) and titanium nitride (TiN) without including a second conductive layer (e.g., a second electrically conductive layer) formed by stacking indium tin oxide (ITO) and silver (Ag). However, the present disclosure is not limited to the aforementioned example.

The emission structure EMS may be on the anode electrodes AE. The emission structure EMS may emit light based on an electrical signal defined between the anode electrode AE and the cathode electrode CE.

In embodiments, the emission structure EMS may be formed through a scheme or process such as vacuum deposition, spin coating, inkjet printing, and/or the like, but embodiments are not limited thereto.

The emission structure EMS may include a multilayer structure. For example, the emission structure EMS may include a hole transport part HTU, an emission layer EML, and an electron transport part ETU. The emission structure EMS may include various suitable organic materials and, in an embodiment, may further include inorganic materials such as metal-containing compounds and/or quantum dots.

The hole transport part HTU may include a multilayer structure including a plurality of layers respectively including different materials. For example, the hole transport part HTU may include at least one selected from a hole injection layer and a hole transport layer and, in an embodiment, may further include an auxiliary emission layer, an electron blocking layer, and/or the like.

The hole injection layer may be a layer that performs and/or improves a function of injecting holes from the anode electrode AE into another adjacent organic layer. The hole transport layer may be a layer that provides received holes to the emission layer EML. The auxiliary emission layer may compensate for a resonance distance based on a wavelength of light provided from the emission layer EML. The electron blocking layer may be a layer that prevents or reduces injection of electrons from the electron transport part ETU, thus reducing the number of carriers (e.g., holes or electrons) displaced from the emission layer EML.

For example, the hole transport part HTU may have a multilayer structure, e.g., including hole injection layer/hole transport layer, hole injection layer/hole transport layer/auxiliary emission layer, hole injection layer/auxiliary emission layer, hole transport layer/auxiliary emission layer, electron blocking layer/hole injection layer/hole transport layer, sequentially-provided hole transport layers containing different materials, or hole injection layer/hole transport layer/electron blocking layer. However, the present disclosure is not limited to the aforementioned example.

In an embodiment, the hole transport part HTU may include various suitable organic materials having hole transport properties. For example, the hole transport part HTU may include one or more selected from the group consisting of m-MTDATA (Chemical Formula 2), NPB (Chemical Formula 3), TCTA (Chemical Formula 4), S-HTL1 (Chemical Formula 5), S-HTL2 (Chemical Formula 6), S-HTL3 (Chemical Formula 7), and S-HTL4 (Chemical Formula 8). However, the present disclosure is not limited to the aforementioned example. In an embodiment, the hole transport part HTU may further include any suitable spin-coated polymer and/or the like generally available in the art.

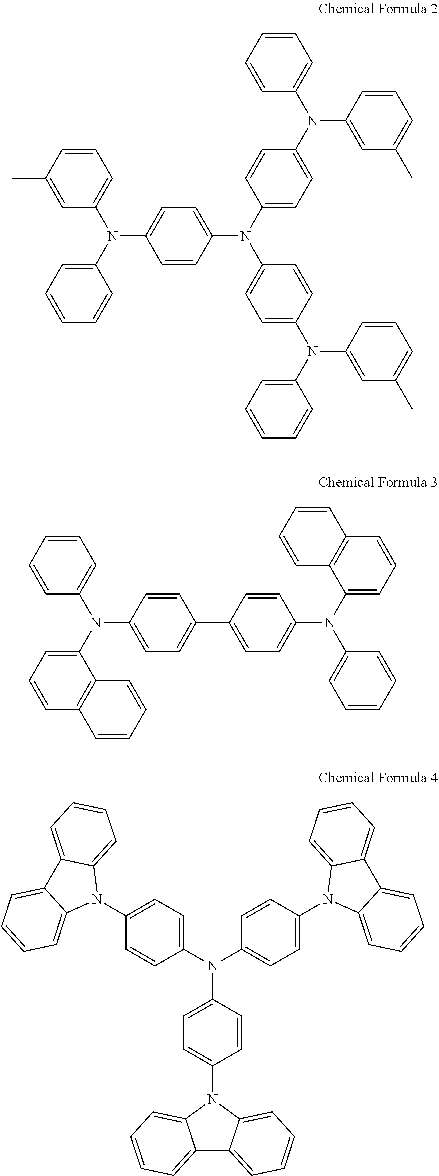

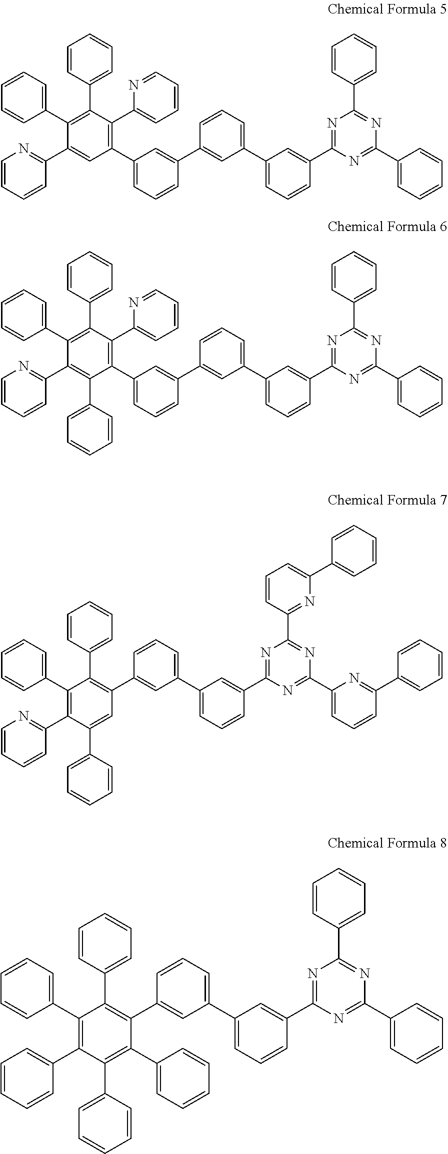 [SMILES: c1ccc(-c2nc(-c3ccccc3)nc(-c3cccc(-c4cccc(-c5cccc(-c6cc(-c7ccccn7)c(-c7ccccc7)c(-c7ccccc7)c6-c6ccccn6)c5)c4)c3)n2)cc1 ; c1ccc(-c2nc(-c3ccccc3)nc(-c3cccc(-c4cccc(-c5cccc(-c6c(-c7ccccc7)c(-c7ccccn7)c(-c7ccccc7)c(-c7ccccc7)c6-c6ccccn6)c5)c4)c3)n2)cc1 ; c1ccc(-c2cccc(-c3nc(-c4cccc(-c5cccc(-c6cc(-c7ccccc7)c(-c7ccccn7)c(-c7ccccc7)c6-c6ccccc6)c5)c4)nc(-c4cccc(-c5ccccc5)n4)n3)n2)cc1 ; c1ccc(-c2nc(-c3ccccc3)nc(-c3cccc(-c4cccc(-c5c(-c6ccccc6)c(-c6ccccc6)c(-c6ccccc6)c(-c6ccccc6)c5-c5ccccc5)c4)c3)n2)cc1]

The hole transport part HTU may further include a p-dopant as well as including the aforementioned materials. The p-dopant may be uniformly or unevenly dispersed in some layers that form the hole transport part HTU. The p-dopant may include NDP-9 (Chemical Formula 9). However, the present disclosure is not limited to the aforementioned example. For example, the p-dopant may further include one or more of MoO3 or F4-TCNQ (2,3,5,6-tetrafluoro-7,7,8,8-tetracyanoquinodimethane).

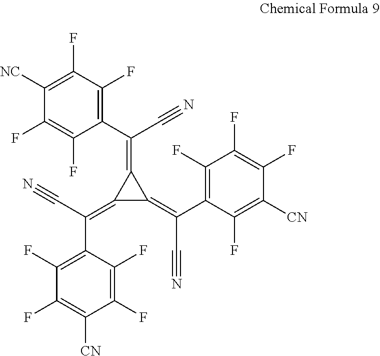 [SMILES: N#C/C(=C1/C(=C(\C#N)c2c(F)c(F)c(F)c(C#N)c2F)/C1=C(\C#N)c1c(F)c(F)c(C#N)c(F)c1F)c1c(F)c(F)c(C#N)c(F)c1F]

In an embodiment, the hole transport part HTU for the third sub-pixel SP3 may include material that is at least partially different from the material of the hole transport part HTU for each of the first and second sub-pixels SP1 and SP2.

In an embodiment, the hole transport part HTU may include, as a plurality of layers included in the light emitting element LD for the first sub-pixel SP1, a first hole injection layer including one or more selected from among S-HTL1 to S-HTL4, a first hole transport layer including NPB, and a first electron blocking layer including TCTA. For example, the first hole injection layer, the first hole transport layer, and the first electron blocking layer may be successively stacked on the first anode electrode AE1.

In an embodiment, the first hole injection layer may have a thickness in a range from approximately 25 Å to approximately 75 Å. For example, the first hole injection layer may have a thickness of approximately 50 Å. The first hole transport layer may have a thickness in a range from approximately 800 Å to approximately 1500 Å. For example, the first hole transport layer may have a thickness of approximately 1150 Å. The first electron blocking layer may have a thickness in a range from approximately 700 Å to approximately 900 Å. For example, the first electron blocking layer may have a thickness of approximately 800 Å. However, the present disclosure is not limited to the aforementioned example.

In an embodiment, the hole transport part HTU may include, as a plurality of layers included in the light emitting element LD for the second sub-pixel SP2, a second hole injection layer including one or more among S-HTL1 to S-HTL4, a second hole transport layer including NPB, and a second electron blocking layer including TCTA. For example, the second hole injection layer, the second hole transport layer, and the second electron blocking layer may be successively stacked.

In an embodiment, the second hole injection layer may have the same thickness as the first hole injection layer. The second hole transport layer may have the same thickness as the first hole transport layer. The second electron blocking layer may have a thickness less than that of the first electron blocking layer.

In an embodiment, the second hole injection layer may have a thickness in a range from approximately 25 Å to approximately 75 Å. For example, the second hole injection layer may have a thickness of approximately 50 Å. The second hole transport layer may have a thickness in a range from approximately 800 Å to approximately 1500 Å. For example, the second hole transport layer may have a thickness of approximately 1150 Å. The second electron blocking layer may have a thickness in a range from approximately 350 Å to approximately 600 Å. For example, the second electron blocking layer may have a thickness of approximately 475 Å. However, the present disclosure is not limited to the aforementioned example.

In an embodiment, the hole transport part HTU may include, as a plurality of layers included in the light emitting element LD for the third sub-pixel SP3, a third hole injection layer including NPB doped with NDP-9, a third hole transport layer including NPB, and a third electron blocking layer including M-MTDATA. For example, the third hole injection layer, the third hole transport layer, and the third electron blocking layer may be successively stacked on the third anode electrode AE3.

In an embodiment, the third hole injection layer may have a thickness in a range from approximately 25 Å to approximately 75 Å. For example, the third hole injection layer may have a thickness of approximately 50 Å. The third hole transport layer may have a thickness in a range from approximately 1150 Å to approximately 1300 Å. For example, the third hole transport layer may have a thickness of approximately 1225 Å. The third electron blocking layer may have a thickness in a range from approximately 25 Å to approximately 75 Å. For example, the third electron blocking layer may have a thickness of approximately 50 Å. However, the present disclosure is not limited to the aforementioned example.

The display device 100 in accordance with an embodiment may include the lens-array layer LA, and the light emitting element LD may be configured to output light in one color coordinate range, thus providing a display structure with high light emitting efficiency characteristics.

In an embodiment, in the light emitting element LD, the thickness of the hole transport layer may be adjusted to control the color coordinate range. In the case where the thickness of the hole transport layer changes, light resonance characteristics in the light emitting element LD may change, thus making it possible to change the color coordinates of light.

The emission layer EML may generate light based on current applied thereto. The emission layer EML may be between the hole transport part HTU and the electron transport part ETU.

The emission layer EML may include material capable of emitting light of one color. The emission layer EML may include a host and a dopant. The host of the emission layer EML may be emission material capable of capturing carriers (electrons and holes) for light generation, thus inducing efficient exciton generation. The dopant may include a phosphorescent dopant or a fluorescent dopant. In an embodiment, examples of the dopant are not specifically limited. In an embodiment, the dopant may include an organic material, and may include a metal complex and/or the like. In an embodiment, the dopant may be included at a rate of approximately 0.01 wt % to approximately 20 wt % with respect to the entirety of the corresponding emission layer EML. However, the present disclosure is not limited to the aforementioned example.

As described above, the first emission structure EMS1, the second emission structure EMS2, and the third emission structure EMS3 may emit light of different colors. For example, the first emission structure EMS1 may emit light of a red color, the second emission structure EMS2 may emit light of a green color, and the third emission structure EMS3 may emit light of a blue color.

For example, the first to third emission layers EML1 to EML3 may include different emission materials.

The first emission layer EML1 may include an emission material the emits light of a red color. For example, the first emission layer EML1 may include TPBI (Chemical Formula 10) as a host, and include Ir(dmppy-ph)2(tmd) (Chemical Formula 11) as a red dopant. However, the present disclosure is not limited to the aforementioned example.

The second emission layer EML2 may include an emission material the emits light of a green color. For example, the second emission layer EML2 may include TPBI as a host, and include Irppy3 (Chemical Formula 12) as a green dopant. However, the present disclosure is not limited to the aforementioned example.

The third emission layer EML3 may include an emission material the emits light of a blue color. For example, the third emission layer EML3 may include a blue host represented by the following Chemical Formula 13 as a host, and include a blue dopant represented by the following Chemical Formula 14. For reference, in Chemical Formula 13, D represents deuterium, which may also be referred to as heavy hydrogen.

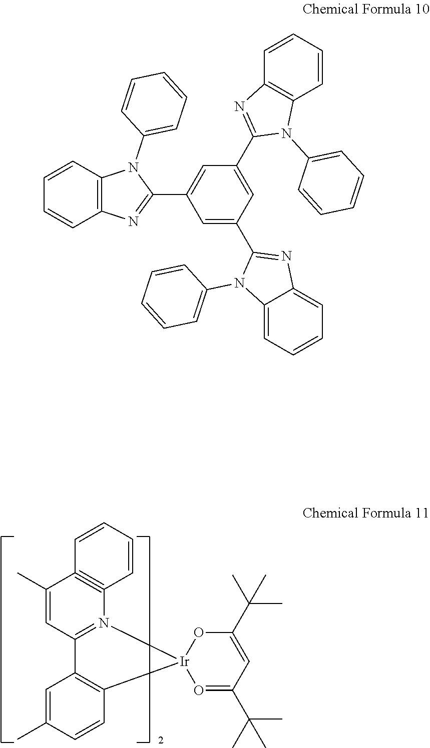

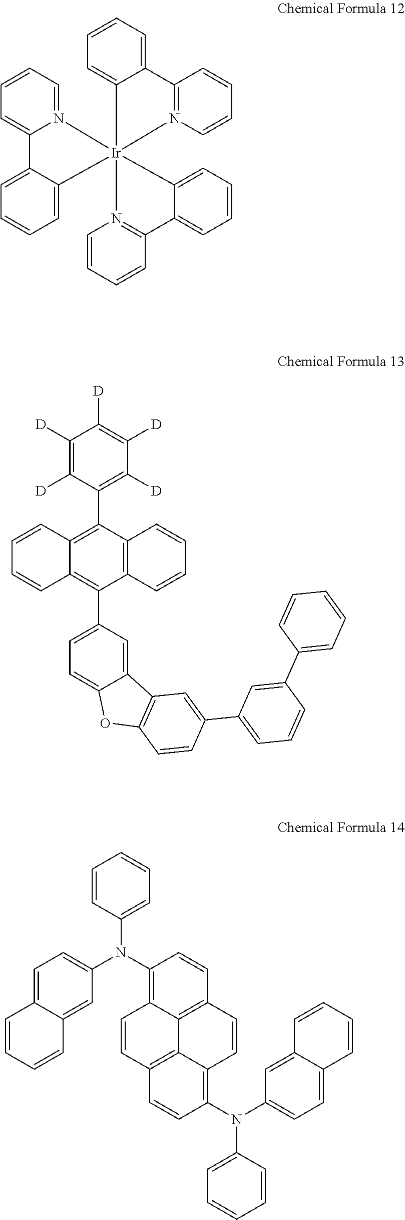

The first emission layer EML1 may have a thickness in a range from approximately 320 Å to approximately 520 Å. For example, the first emission layer EML1 may have a thickness of approximately 420 Å. However, the present disclosure is not limited to the aforementioned example.

The second emission layer EML2 may have a thickness less than that of the first emission layer EML1. The second emission layer EML2 may have a thickness in a range from approximately 280 Å to approximately 480 Å. For example, the second emission layer EML2 may have a thickness of approximately 380 Å. However, the present disclosure is not limited to the aforementioned example.

The third emission layer EML3 may have a thickness less than that of the second emission layer EML2. The third emission layer EML3 may have a thickness in a range from approximately 150 Å to approximately 250 Å. For example, the third emission layer EML3 may have a thickness of approximately 200 Å. However, the present disclosure is not limited to the aforementioned example.

The electron transport part ETU may include a multilayer structure including a plurality of layers respectively including different materials. The electron transport part ETU may include at least one selected from an electron injection layer and an electron transport layer and, in an embodiment, may further include an electron buffer layer, a hole blocking layer, and/or the like.

The electron injection layer may be a layer that performs and/or improves a function of injecting electrons from the cathode electrode CE into another adjacent organic layer. The electron transport layer may be a layer that provides received electrons to the emission layer EML. The hole blocking layer may be a layer that prevents or reduces injection of holes from the hole transport part HTU, thus reducing the number of carriers displaced from the emission layer EML.

For example, the electron transport part ETU may have a multilayer structure, e.g., including electron transport layer/electron injection layer, hole blocking layer/electron transport layer/electron injection layer, electron control layer/electron transport layer/electron injection layer, or buffer layer/electron transport layer/electron injection layer. However, the present disclosure is not limited to the aforementioned example.

In an embodiment, the electron transport part ETU may include various compounds having electron transport properties. For example, the electron transport part ETU may include non-metal containing organic materials, and may also include metal-containing organic materials and/or various suitable metal materials (e.g., alkali earth metals and/or rare earth metals). For example, the electron transport part ETU may include one or more selected from the group consisting of T2T (Chemical Formula 15), TPM-TAZ (Chemical Formula 16), LiQ (lithium quinolate) (Chemical Formula 17), and Yb. However, the present disclosure is not limited to the aforementioned examples.

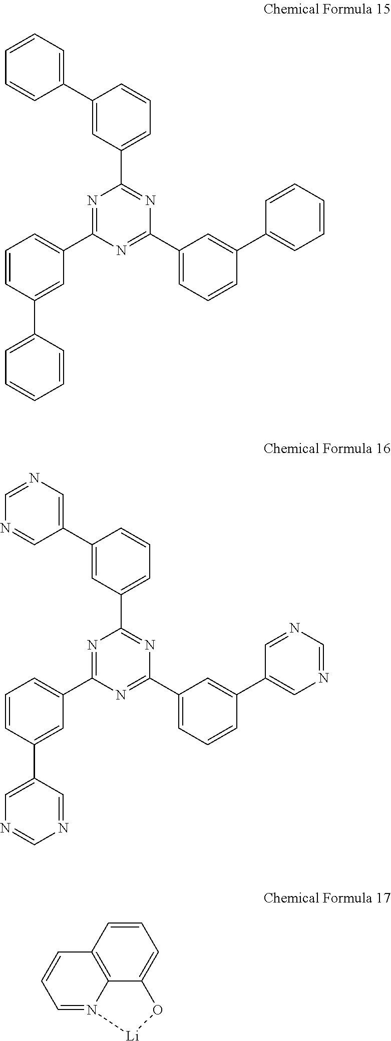

In an embodiment, the respective electron transport parts ETU for the first sub-pixel SP1, the second sub-pixel SP2, and the third sub-pixel SP3 may have the same material, and may have the same thickness.

For example, in each of the first sub-pixel SP1, the second sub-pixel SP2, and the third sub-pixel SP3 that have the same material and thickness, the electron transport part ETU may include sequentially placed layers, including a hole blocking layer, an electron transport layer on the hole blocking layer, and an electron injection layer on the electron transport layer. In an embodiment, in each of the first sub-pixel SP1, the second sub-pixel SP2, and the third sub-pixel SP3, the electron transport part ETU may include a hole blocking layer including T2T, an electron transport layer including TPM-TAZ, and an electron injection layer including Yb.

In an embodiment, in each of the first sub-pixel SP1, the second sub-pixel SP2, and the third sub-pixel SP3, the hole blocking layer may have a thickness in a range from approximately 25 Å to approximately 75 Å. For example, the hole blocking layer may have a thickness of approximately 50 Å. The electron transport layer may have a thickness in a range from approximately 250 Å to approximately 370 Å. For example, the electron transport layer may have a thickness of approximately 310 Å. The electron injection layer may have a thickness in a range from approximately 7 Å to approximately 13 Å. For example, the electron injection layer may have a thickness of approximately 10 Å. However, the present disclosure is not limited to the aforementioned example.

The cathode electrode CE may be on the capping layer CPL in the first to third sub-pixels SP1, SP2, and SP3. The cathode electrode CE may be over the first to third sub-pixels SP1 to SP3. As described above, the cathode electrode CE may include various suitable conductive materials (e.g., electrically conductive materials).

The cathode electrode CE may have a thickness capable of improving or optimizing the light efficiency of the light emitting element LD. For example, the cathode electrode CE may have a thickness in a range from approximately 70 Å to approximately 140 Å. In an embodiment, the cathode electrode CE may have a thickness in a range from approximately 80 Å to approximately 110 Å. In the case where the thickness of the cathode electrode CE exceeds an upper limit of the aforementioned numeral range or falls below a lower limit of the numeral range, the light emitting element LD may not have sufficient light efficiency, and it may be difficult to output light within a suitable or appropriate color coordinate range.

In accordance with an embodiment, each of the light emitting elements LD of the first to third sub-pixels SP1 to SP3 (for example, each of the first to third emission layers EML1 to EML3) may emit light within one color coordinate range.

The color coordinates in this specification refers to color coordinates in the International Commission on Illumination (CIE) 1931 coordinate system. The color coordinates may refer to set or specific coordinates based on an x-coordinate value and a y-coordinate value in graph data based on the x-axis and y-axis, and may be specified to a corresponding color based on the associated x-coordinate value and y-coordinate value.

In an embodiment, color coordinates of target light to be measured may be determined using any suitable equipment generally used in the art. For example, the color coordinates may be measured using a spectrophotometer from Minolta (model: CM-3700A). Here, the measurement equipment is not limited to specific target equipment.

In this specification, the color coordinates may be measured based on light observed in the front of the display device 100.

In an embodiment, the display device 100 may provide light of one color having one output-light color coordinate range. For example, the display device 100 may provide light of a first color having a first output-light color coordinate range, light of a second color having a second output-light color coordinate range, and light of a third color having a third output-light color coordinate range.

Here, light of one color that the display device 100 emits to the outside may be provided by passing through the lens-array layer LA (e.g., the lens LS).

For example, the lens LS may include a first lens LS1 overlapping the first emission structure EMS1 in a plan view and included in the first sub-pixel SP1, a second lens LS2 overlapping the second emission structure EMS2 in a plan view and included in the second sub-pixel SP2, and a third lens LS3 overlapping the third emission structure EMS3 in a plan view and included in the third sub-pixel SP3.

Light provided from the first emission structure EMS1 may pass through the first lens LS1 and be emitted to the outside. Light provided from the second emission structure EMS2 may pass through the second lens LS2 and be emitted to the outside. Light provided from the third emission structure EMS3 may pass through the third lens LS3 and be emitted to the outside.

Because the lens LS has a relatively high refractive index, optical information (e.g., color coordinates) about light that has passed through the lens LS may differ from optical information (e.g., color coordinates) about the light before passing through the lens LS. For example, the light that has passed through the lens LS may have a wavelength band of a relatively short wavelength compared to the light before passing through the lens LS.

In an embodiment, the first to third emission layers EML1 to EML3 may be configured to output light of respective relatively long wavelengths compared to light visible through the first to third sub-pixels SP1 to SP3. In other words, in an embodiment, the first to third emission layers EML1 to EML3 may be designed to provide light having relatively long wavelengths, compared to light ultimately intended to be provided from the display device 100.

Accordingly, light emitted from the light emitting elements LD may be outputted to the outside through an intended light path, and light with intended color characteristics may be visible from the outside.

The first emission layer EML1 (the first emission structure EMS1) may provide (e.g., emit) a light of a first base color (e.g., a first base light) having a first base color coordinate range. The light of the first base color is intended to provide a light of a first color (e.g., a first light) having first output-light color coordinates, and may be transformed into the light of the first color by passing through the lens-array layer LA (e.g., the lens LS).

In an embodiment, an x-coordinate value of the first base color coordinates may be in a range from 0.680 to 0.695. An x-coordinate value of the first output-light color coordinates may be in a range from 0.670 to 0.685. For example, based on whether light is before or after passing through the lens-array layer LA, variance (x) in x-coordinate value of the light in the first sub-pixel SP1 may be in a range from −0.015 to −0.01.

In an embodiment, a y-coordinate value of the first base color coordinates may be in a range from 0.305 to 0.315. A y-coordinate value of the first output-light color coordinates may be in a range from 0.317 to 0.321. For example, based on whether light is before or after passing through the lens-array layer LA, variance (y) in y-coordinate value of the light in the first sub-pixel SP1 may be in a range from 0.002 to 0.016.

The second emission layer EML2 (the second emission structure EMS2) may provide (e.g., emit) a light of a second base color (e.g., a second base light) having a second base color coordinate range. The light of the second base color is intended to provide a light of a second color (e.g., a second light) having second output-light color coordinates, and may be transformed into the light of the second color by passing through the lens-array layer LA (e.g., the lens LS).

In an embodiment, an x-coordinate value of the second base color coordinates may be in a range from 0.250 to 0.295. An x-coordinate value of the second output-light color coordinates may be in a range from 0.230 to 0.265. For example, based on whether light is before or after passing through the lens-array layer LA, variance (x) in x-coordinate value of light in the second sub-pixel SP2 may be in a range from −0.030 to −0.020.

In an embodiment, a y-coordinate value of the second base color coordinates may be in a range from 0.679 to 0.711. A y-coordinate value of the second output-light color coordinates may be in a range from 0.703 to 0.727. For example, based on whether light is before or after passing through the lens-array layer LA, variance (y) in y-coordinate value of the light in the second sub-pixel SP2 may be in a range from 0.008 to 0.048.

The third emission layer EML3 (the third emission structure EMS3) may provide (e.g., emit) a light of a third base color (e.g., a third base light) having a third base color coordinate range. The light of the third base color is intended to provide a light of a third color (e.g., a third light) having third output-light color coordinates, and may be transformed into the light of the third color by passing through the lens-array layer LA (e.g., the lens LS).

In an embodiment, an x-coordinate value of the third base color coordinates may be in a range from 0.100 to 0.130. An x-coordinate value of the third output-light color coordinates may be in a range from 0.128 to 0.141. For example, based on whether light is before or after passing through the lens-array layer LA, variance (x) in x-coordinate value of the light in the third sub-pixel SP3 may be in a range from 0.002 to 0.041.

In an embodiment, a y-coordinate value of the third base color coordinates may be in a range from 0.060 to 0.100. A y-coordinate value of the third output-light color coordinates may be in a range from 0.040 to 0.060. For example, based on whether light is before or after passing through the lens-array layer LA, variance (y) in y-coordinate value of the light in the third sub-pixel SP3 may be in a range from −0.040 to −0.010.

The above-mentioned first to third output-light color coordinates may pertain to a set or specific numeral range selected to enhance the light emitting efficiency of the light emitting element LD.

For example, the first to third emission layers EML1 to EML3 may be provided to emit light having the aforementioned first to third output-light color coordinates. Hence, each of the first to third sub-pixels SP1 to SP3 including the first to third emission layers EML1 to EML3 may have excellent light emitting efficiency.

In other words, the disposition of the lens-array layer LA allows for set or precise definition of a light output path. Therefore, although the optical information may change depending on disposition of an additional element, embodiments of the present disclosure may be configured to output light having the first to third base color coordinates, so that light having first to third output-light color coordinates can be outputted. As a result, with suitably or satisfactorily high light emitting efficiency, the display device 100 having high performance (e.g., high resolution) may implement a full-color display structure having valid color coordinates.

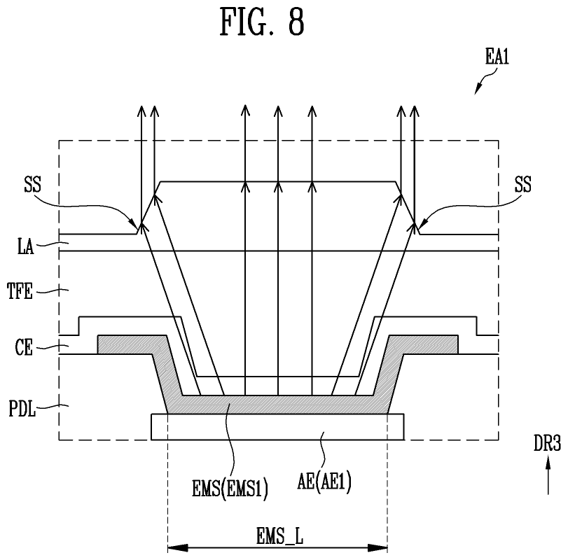

Hereinafter, the shape of the lens-array layer LA and the corresponding light output path of the display device 100 in accordance with an embodiment will be described with reference to FIGS. 8 to 12.

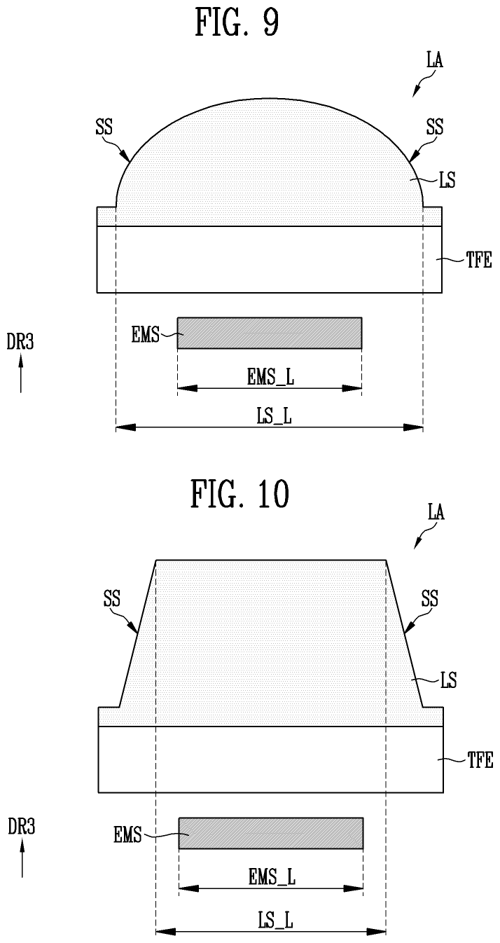

FIG. 8 is a schematic enlarged view of area EA1 of FIG. 6. FIGS. 9 to 12 are schematic cross-sectional views each illustrating a lens-array layer LA in accordance with an embodiment.

For the sake of explanation, FIG. 8 illustrates the light output path of the display device 100 based on the first emission structure EMS1. Here, the technical characteristics described below with reference to the first emission structure EMS1 may be equally applied to the second and third emission structures EMS2 and EMS3.

Referring to FIG. 8, light provided from the emission structure EMS (e.g., the emission layer EML) may be emitted to the outside through a plurality of layers and the lens-array layer LA.

Light provided from the emission structure EMS may be emitted in a vertical direction (e.g., the third direction DR3) based on the plane direction of the substrate SUB, and may be emitted in a diagonal direction different from the vertical direction.

In an embodiment, the emission structure EMS may have an emission length EMS_L between adjacent pixel defining layers PDL. In an embodiment, the emission length EMS_L may be designed to correspond to a width of the lens LS (e.g., a length of an upper side or a lower side of a cross-section of the lens LS, e.g., a lens length LS_L (refer to FIG. 9) or a lens width). Contents pertaining to the aforementioned design will be described below with reference to FIGS. 9 to 12.

In an embodiment, the lens LS in the lens-array layer LA may include side surfaces SS extending in diagonal directions with respect to the vertical direction (e.g., the third direction DR3). The side surfaces SS may change paths of light incident in relatively oblique directions to the vertical direction.

As a result, light provided from the emission structure EMS may be outputted outward substantially in the vertical direction. In this case, the luminance of light perceived in the front of the display device 100 may be enhanced, and a light image having a higher luminance under the same power conditions can be implemented.

Because the lens-array layer LA forms a light refractive structure, the color coordinates of light applied thereto may be shifted. However, as described above, light provided from the emission structure EMS may be designed to have a long wavelength, compared to light to be ultimately provided, and thus may be provided to enable light to be provided from the display device 100 to have suitable color coordinate information.

FIGS. 9 to 12 illustrate various suitable embodiments of the lens LS in accordance with embodiments of the present disclosure. For the sake of explanation, FIGS. 9 to 12 illustrate the lens-array layer LA on the encapsulation layer TFE, schematically showing cross-sectional structures of lenses LS. The lenses LS illustrated in FIGS. 9 to 12 may be defined in any one of the sub-pixels SP. For the sake of explanation, FIGS. 9 to 12 schematically illustrate, under the encapsulation layer TFE, an area where the emission length EMS_L is defined as a portion of the emission structure EMS.

Referring to FIG. 9, the lens LS in accordance with an embodiment may have a semi-circular cross-section. For example, the lens LS may have a curved side surface SS. Hence, the lens LS may have a hemispherical structure. In this case, an interface on which light refraction may occur may further expand. In an embodiment, the lens length LS_L may correspond to a bottom side of the hemispherical structure, and may be in a range from 50% to 150% of the emission length EMS_L. In this case, the light path may be suitably defined, and suitable or sufficient light efficiency can be secured.

Referring to FIG. 10, the lens LS in accordance with an embodiment may have a trapezoidal cross-section. For example, the lens LS may have a diagonal side surface SS. For example, the side surface SS may substantially extend in one direction without forming a curved surface. In an embodiment, the side surface SS may form an included angle in a range from approximately 45° to approximately 60° with respect to a base of the lens-array layer LA. In an embodiment, the side surface SS may form an included angle in a range from approximately 50° to approximately 70° with respect to the base of the lens-array layer LA. However, the present disclosure is not limited to the aforementioned example. Hence, the lens LS may have a truncated quadrangular pyramid structure. In an embodiment, the lens length LS_L may correspond to a top side of the lens LS, and may be in a range from 80% to 120% of the emission length EMS_L. In this case, the light path may be suitably defined, and suitable or sufficient light efficiency can be secured.

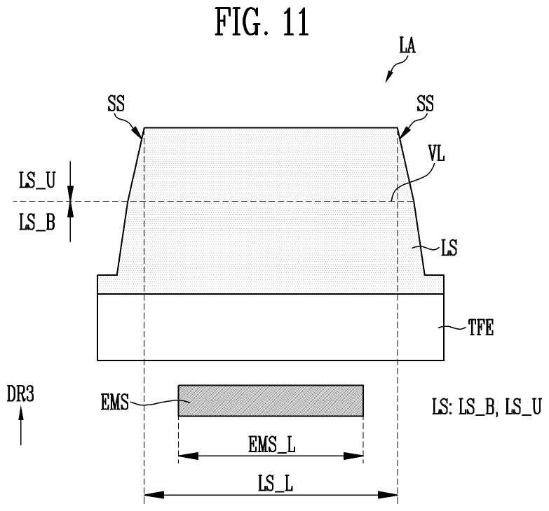

Referring to FIG. 11, the lens LS in accordance with an embodiment may have a cross-sectional structure in which a plurality of (e.g., two) trapezoids are successively placed. The lens LS may have a cross-sectional structure including a lower lens part LS_B and an upper lens part LS_U provided on the lower lens part LS_B. The lower lens part LS_B may have a first trapezoidal cross-section. The upper lens part LS_U may have a second trapezoidal cross-section that is not in a similar geometric relationship with the first trapezoidal cross-section. For example, the lens LS may be bent on at least a portion thereof, thus having side surfaces SS that extend in different directions. The side surfaces SS may extend in a first diagonal direction in the lower lens part LS_B and extend in a second diagonal direction different from the first diagonal direction in the upper lens part LS_U. Hence, the lens LS may have a structure in which a second truncated quadrangular pyramid is on a first truncated quadrangular pyramid. In an embodiment, the lens length LS_L may correspond to a top side of the lens LS, and may be in a range from 80% to 120% of the emission length EMS_L.

Referring to FIG. 12, the lens LS in accordance with an embodiment may have a cross-sectional structure in which a trapezoidal cross-sectional structure and a semi-circular cross-sectional structure are successively provided. The lens LS may have a cross-sectional structure including a lower lens part LS_B and an upper lens part LS_U provided on the lower lens part LS_B. The lower lens part LS_B may have a trapezoidal cross-section. The upper lens part LS_U may have a semi-circular cross-section. Hence, the lens LS may have a structure in which a hemisphere is on a truncated quadrangular pyramid. The lens length LS_L may be a length of a boundary line between the lower lens part LS_B and the upper lens part LS_U, and may be in a range from 80% to 120% of the emission length EMS_L. In an embodiment, the lens length LS_L may be in a range from 50% to 150% of the emission length EMS_L.

In an embodiment, in the case where the lens LS has a cross-sectional structure illustrated in FIGS. 9 to 12, a display device 100 including a light emitting element LD having excellent light emitting efficiency may be provided.

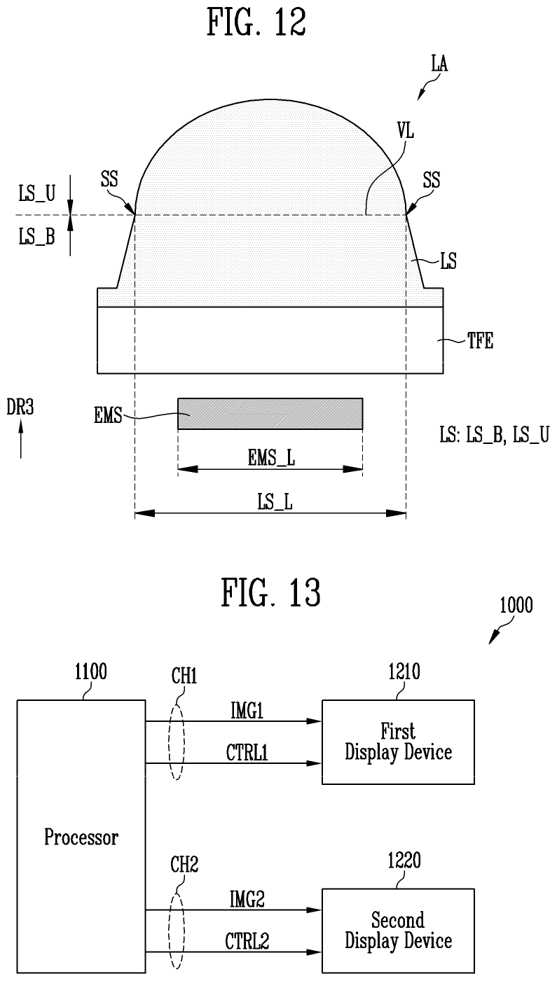

FIG. 13 is a block diagram illustrating an embodiment of a display system.

Referring to FIG. 13, the display system 1000 may include a processor 1100, and one or more display devices 1210 and 1220.

The processor 1100 may perform various suitable tasks and operations. In embodiments, the processor 1010 may include an application processor, a graphic processor, a microprocessor, a central processing unit (CPU), and/or the like. The processor 110 may be connected to the other components of the display system 1000 through a bus system to control the components.

In FIG. 13, there is illustrated the case where the display system 1000 includes the first and second display devices 1210 and 1220. The processor 1100 may be connected to the first display device 1210 through a first channel CH1, and may be connected to the second display device 1220 through a second channel CH2.

The processor 1100 may transmit a first image data IMG1 and a first control signal CTRL1 to the first display device 1210 through the first channel CH1. The first display device 1210 may display an image based on the first image data IMG1 and the first control signal CTRL1. The first display device 1210 may be configured in the same manner as the display device 100 described with reference to FIG. 1.

The processor 1100 may transmit a second image data IMG2 and a second control signal CTRL2 to the second display device 1220 through the second channel CH2. The second display device 1220 may display an image based on the second image data IMG2 and the second control signal CTRL2. The second display device 1220 may be configured in the same manner as the display device 100 described with reference to FIG. 1.

The display system 1000 may include computing systems that provide an image display function, such as a portable computer, a mobile phone, a smart phone, a tablet personal computer (tablet PC), a smart watch, a watch phone, a portable multimedia player, a navigation system, and/or an ultra mobile personal computer (UMPC). Furthermore, the display system 1000 may include at least one selected from a head mounted display (HMD), a virtual reality (VR) device, a mixed reality (MR) device, and an augmented reality (AR) device.

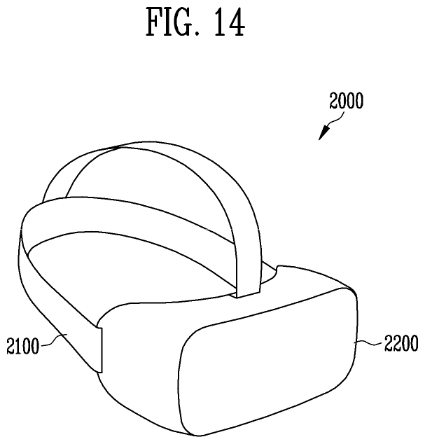

FIG. 14 is a perspective diagram illustrating an application example of the display system of FIG. 13.

Referring to FIG. 14, the display system 1000 of FIG. 13 may be applied to a head mounted display device 2000. The head mounted display device 2000 may be a wearable electronic device, which can be worn on the head of the user.

The head mounted display 2000 may include a head mounting band 2100 and a display device reception casing 2200. The head mounted band 2100 may be connected to the display device reception casing 2200. The head mounted band 2100 may include a horizontal band and/or a vertical band to fasten the head mounted display 2000 to the head of the user. The horizontal band may enclose the sides of the head of the user, and the vertical band may enclose the top of the head of the user. However, embodiments are not limited to the aforementioned example. For example, the head mounted band 2100 may be implemented in the form of eyeglass frames, a helmet, and/or the like.

The display device reception casing 2200 may receive the first and second display devices 1210 and 1220 of FIG. 13. The display device reception casing 2200 may further receive the processor 1100 of FIG. 13.

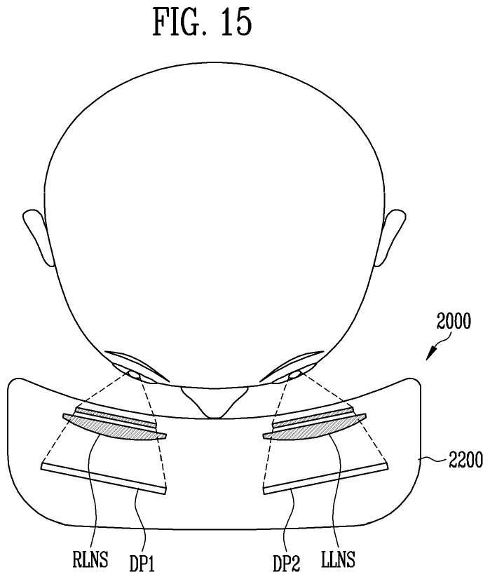

FIG. 15 is a diagram illustrating the head mounted display device 2000 of FIG. 14 that is worn on a user.

Referring to FIG. 15, the first display panel DP1 of the first display device 1210 and the second display panel DP2 of the second display device 1220 are disposed in the head mounted display 2000. The head mounted display 2000 may further include one or more lenses LLNS and RLNS.

In the display device reception casing 2200, a right-eye lens RLNS may be between the first display panel DP1 and the right eye of the user. In the display device reception casing 2200, a left-eye lens LLNS may be between the second display panel DP2 and the left eye of the user.

An image outputted from the first display panel DP1 can be viewed by the right eye of the user through the right-eye lens RLNS. The right lens RLNS may refract light emitted from the first display panel DP1 toward the right eye of the user. The right-eye lens RLNS may perform an optical function to adjust a viewing distance between the first display panel DP1 and the right eye of the user.

An image outputted from the second display panel DP2 can be viewed by the left eye of the user through the left-eye lens LLNS. The left lens LLNS may refract light emitted from the second display panel DP2 toward the left eye of the user. The left-eye lens LLNS may perform an optical function to adjust a viewing distance between the second display panel DP2 and the left eye of the user.

In embodiments, each of the right-eye lens RLNS and the left-eye lens LLNS may include an optical lens having a pancake-shaped cross-section. In embodiments, each of the right-eye lens RLNS and the left-eye lens LLNS may include a multi-channel lens including sub-areas having different optical characteristics. In this case, each display panel may output images respectively corresponding to sub-areas of the multi-channel lens. The output images may be viewed to the user through the corresponding sub-areas.

### 2. Experimental Example

Hereinafter, embodiments of the present disclosure will be described in more detail based on experimental examples. Here, the following experimental examples are provided merely for further detailed explanation of the present disclosure, and the present disclosure is not limited to embodiments manufactured according to the following manufacturing examples.

### 1 Experimental Example 1—Analysis of Light Emitting Efficiency Tendency by Color Coordinates/Third Sub-Pixel SP3

### Manufacturing Example 1

A Si wafer substrate (Silicon wafer product from SK Siltron) was provided in a size of 50 mm×50 mm and installed in a vacuum deposition apparatus. On an anode electrode AE (ITO/Ag stacked on Al/TiN) on a glass substrate, a hole injection layer was formed by co-depositing NPB and NDP-9 to a thickness of 50 Å, a hole transport layer was formed by depositing NPB to a thickness of 1150 Å, and an electron blocking layer was formed by depositing M-MTDATA to a thickness of 50 Å. Thereafter, an emission layer EML with a thickness of 200 Å was formed on the electron blocking layer by co-depositing a blue host (Chemical Formula 13) and a blue dopant (Chemical Formula 14) at a volume ratio of 100:1. A hole blocking layer was formed on the emission layer EML by depositing T2T to a thickness of 50 Å. A hole transport layer having a thickness of 310 Å was formed on the hole blocking layer by co-depositing TMP_TAZ and LiQ at a volume ratio of 1:1. An electron Injection layer was formed on the hole transport layer by depositing Yb to a thickness of 10 Å. As a result, an emission structure EMS (e.g., the third emission structure EMS3) was provided. Subsequently, a cathode electrode having a thickness of 100 Å was formed on the electron injection layer by co-depositing Ag and Mg at a volume ratio of 9:1 to a thickness of 100 Å. A CPL material (Chemical Formula 1) was formed on the cathode electrode, thus leading to the fabrication of a light emitting element LD that can be formed in the third sub-pixel SP3. For reference, commercially marketed materials were used as respective materials for forming the light emitting element LD.

### Manufacturing Example 2

Except for forming NPB as the hole transport layer on the hole injection layer to a thickness of 1170 Å, a light emitting element LD according to Manufacturing Example 2, which can be formed in the third sub-pixel SP3, was manufactured by the same method as Manufacturing Example 1.

### Manufacturing Example 3

Except for forming NPB as the hole transport layer on the hole injection layer to a thickness of 1190 Å, a light emitting element LD according to Manufacturing Example 3, which can be formed in the third sub-pixel SP3, was manufactured by the same method as Manufacturing Example 1.

### Manufacturing Example 4

Except for forming NPB as the hole transport layer on the hole injection layer to a thickness of 1210 Å, a light emitting element LD according to Manufacturing Example 4, which can be formed in the third sub-pixel SP3, was manufactured by the same method as Manufacturing Example 1.

### Manufacturing Example 5

Except for forming NPB as the hole transport layer on the hole injection layer to a thickness of 1230 Å, a light emitting element LD according to Manufacturing Example 5, which can be formed in the third sub-pixel SP3, was manufactured by the same method as Manufacturing Example 1.

### Manufacturing Example 6

Except for forming NPB as the hole transport layer on the hole injection layer to a thickness of 1250 Å, a light emitting element LD according to Manufacturing Example 6, which can be formed in the third sub-pixel SP3, was manufactured by the same method as Manufacturing Example 1.

### Manufacturing Example 7

Except for forming NPB as the hole transport layer on the hole injection layer to a thickness of 1270 Å, a light emitting element LD according to Manufacturing Example 7, which can be formed in the third sub-pixel SP3, was manufactured by the same method as Manufacturing Example 1.

An encapsulation layer TFE was manufactured by successively forming silicon oxide (SiOx)/silicon nitride (SiNx)/silicon oxide (SiOx) through a chemical vapor deposition (CVD) process on the light emitting elements LD manufactured according to each of the manufacturing examples. A lens LS having a circular upper portion (e.g., the lens LS described with reference to FIG. 12) was patterned on a surface of the encapsulation layer TFE through a photolithography and a dry etching process. In the present experimental example, the lens LS on the light emitting elements LD according to each of the manufacturing examples has the same shape.

The color characteristics of light before and after passing through the lenses LS were measured using the manufactured display device 100. In more detail, optical characteristics of light that has passed through the encapsulation layer TFE as light before passing through the lens LS were measured. Optical characteristics of light that has passed through the lens LS as light after passing through the lens LS were measured. The color coordinates of a target light were measured using a spectrophotometer (Model: CM-3700A) from Minolta. With regard to current efficiency (cd/A) and conversion efficiency (cd/A/y), for reference, the conversion efficiency refers to a value obtained by dividing the current efficiency by a y-coordinate value of the color coordinates. A higher value of the conversion efficiency indicates superior efficiency of the light emitting element LD. An efficiency improvement margin represents a ratio of the conversion efficiency of light after passing through the lens LS to the conversion efficiency of light before passing through the lens LS.

TABLE 1

| | | | | | | | | | — |
|---|---|---|---|---|---|---|---|---|---|
| | | | | | | | | | Effi- |
| | Before passing through lens (LS) | | | | After passing through lens (LS) | | | | ciency |
| | Color | Color | Cur- | Conver- | Color | Color | Cur- | Conver- | improve- |
| | coordi- | coordi- | rent | sion | coordi- | coordi- | rent | sion | ment |
| | nates | nates | Effi- | effi- | nates | nates | Effi- | effi- | margin |
| — | (x) | (y) | ciency | ciency | (x) | (y) | ciency | ciency | (%) |
| Manufac- | 0.143 | 0.04 | 6.5 | 162.5 | 0.147 | 0.028 | 6.5 | 232.1 | 143 |
| turing | | | | | | | | | |
| Exam- | | | | | | | | | |
| ple 1 | | | | | | | | | |
| Manufac- | 0.136 | 0.05 | 7.2 | 144.0 | 0.143 | 0.037 | 9.5 | 256.8 | 178 |
| turing | | | | | | | | | |
| Exam- | | | | | | | | | |
| ple 2 | | | | | | | | | |
| Manufac- | 0.130 | 0.06 | 8.3 | 138.3 | 0.141 | 0.042 | 12.2 | 290.5 | 210 |
| turing | | | | | | | | | |
| Exam- | | | | | | | | | |
| ple 3 | | | | | | | | | |
| Manufac- | 0.122 | 0.07 | 8.8 | 125.7 | 0.137 | 0.049 | 14.3 | 291.8 | 232 |
| turing | | | | | | | | | |
| Exam- | | | | | | | | | |
| ple 4 | | | | | | | | | |
| Manufac- | 0.155 | 0.08 | 9.5 | 118.8 | 0.135 | 0.054 | 15.2 | 281.5 | 237 |
| turing | | | | | | | | | |
| Exam- | | | | | | | | | |
| ple 5 | | | | | | | | | |
| Manufac- | 0.108 | 0.09 | 10.2 | 113.3 | 0.133 | 0.059 | 16.1 | 272.9 | 241 |
| turing | | | | | | | | | |
| Exam- | | | | | | | | | |
| ple 6 | | | | | | | | | |
| Manufac- | 0.103 | 0.1 | 10.3 | 103.0 | 0.128 | 0.067 | 13.2 | 197.0 | 191 |
| turing | | | | | | | | | |
| Exam- | | | | | | | | | |
| ple 7 | | | | | | | | | |

Referring to Table 1, it can be understood that in the case where the color coordinates fall within a set or specific numeral range, the light emitting efficiency is notably excellent. For example, in the third sub-pixel SP2, in the case where the y-coordinate value of the color coordinates is in a range from approximately 0.042 to approximately 0.060, a display device 100 having a light emitting element LD having excellent light emitting efficiency can be provided.

### 2 Experimental Example 2—Analysis of Light Emitting Efficiency Tendency by Color Coordinates/Second Sub-Pixel SP2

### Manufacturing Example 1

A Si wafer substrate (Silicon wafer product from SK Siltron) was provided in a size of 50 mm×50 mm and installed in a vacuum deposition apparatus. A hole injection layer was formed by depositing S-HTL3 (Chemical Formula 7) to a thickness of 50 Å on an anode electrode AE (Al/TiN) on a glass substrate. A hole transport layer was formed by depositing NPB to a thickness of 1150 Å on the hole injection layer. An electron blocking layer was formed by depositing TCTA to a thickness of 350 Å. Thereafter, an emission layer EML having a thickness of 380 Å was formed on the electron blocking layer by co-depositing TBTI as a host and Irppy3 as a green dopant at a volume ratio of 100:12. A hole blocking layer was formed on the emission layer EML by depositing T2T to a thickness of 50 Å. A hole transport layer having a thickness of 310 Å was formed on the hole blocking layer by co-depositing TMP_TAZ and LiQ at a volume ratio of 1:1. An electron injection layer was formed on the hole transport layer by depositing Yb to a thickness of 10 Å. As a result, an emission structure EMS (e.g., the second emission structure EMS2) was provided. Subsequently, a cathode electrode CE having a thickness of 100 Å was formed on the electron injection layer by co-depositing Ag and Mg at a volume ratio of 9:1 to a thickness of 100 Å. A CPL material (Chemical Formula 1) was formed on the cathode electrode CE, thus leading to the fabrication of a light emitting element LD that can be formed in the second sub-pixel SP2. For reference, commercially marketed materials were used as respective materials for forming the light emitting element LD.

### Manufacturing Example 2

Except for forming TCTA as the electron blocking layer on the hole transport layer to a thickness of 370 Å, a light emitting element LD according to Manufacturing Example 2, which can be formed in the second sub-pixel SP2, was manufactured by the same method as Manufacturing Example 1.

### Manufacturing Example 3

Except for forming TCTA as the electron blocking layer on the hole transport layer to a thickness of 390 Å, a light emitting element LD according to Manufacturing Example 2, which can be formed in the second sub-pixel SP2, was manufactured by the same method as Manufacturing Example 1.

### Manufacturing Example 4

Except for forming TCTA as the electron blocking layer on the hole transport layer to a thickness of 410 Å, a light emitting element LD according to Manufacturing Example 4, which can be formed in the second sub-pixel SP2, was manufactured by the same method as Manufacturing Example 1.

### Manufacturing Example 5

Except for forming TCTA as the electron blocking layer on the hole transport layer to a thickness of 430 Å, a light emitting element LD according to Manufacturing Example 5, which can be formed in the second sub-pixel SP2, was manufactured by the same method as Manufacturing Example 1.

### Manufacturing Example 6

Except for forming TCTA as the electron blocking layer on the hole transport layer to a thickness of 450 Å, a light emitting element LD according to Manufacturing Example 6, which can be formed in the second sub-pixel SP2, was manufactured by the same method as Manufacturing Example 1.

### Manufacturing Example 7

Except for forming TCTA as the electron blocking layer on the hole transport layer to a thickness of 470 Å, a light emitting element LD according to Manufacturing Example 7, which can be formed in the second sub-pixel SP2, was manufactured by the same method as Manufacturing Example 1.

### Manufacturing Example 8

Except for forming TCTA as the electron blocking layer on the hole transport layer to a thickness of 490 Å, a light emitting element LD according to Manufacturing Example 8, which can be formed in the second sub-pixel SP2, was manufactured by the same method as Manufacturing Example 1.

### Manufacturing Example 9

Except for forming TCTA as the electron blocking layer on the hole transport layer to a thickness of 510 Å, a light emitting element LD according to Manufacturing Example 9, which can be formed in the second sub-pixel SP2, was manufactured by the same method as Manufacturing Example 1.

### Manufacturing Example 10

Except for forming TCTA as the electron blocking layer on the hole transport layer to a thickness of 530 Å, a light emitting element LD according to Manufacturing Example 10, which can be formed in the second sub-pixel SP2, was manufactured by the same method as Manufacturing Example 1.

### Manufacturing Example 11

Except for forming TCTA as the electron blocking layer on the hole transport layer to a thickness of 550 Å, a light emitting element LD according to Manufacturing Example 11, which can be formed in the second sub-pixel SP2, was manufactured by the same method as Manufacturing Example 1.

A encapsulation layer TFE was manufactured by successively forming silicon oxide (SiOx)/silicon nitride (SiNx)/silicon oxide (SiOx) through a chemical vapor deposition (CVD) process on the light emitting elements LD manufactured according to each of the manufacturing examples. A lens LS having a circular upper portion (e.g., the lens LS described with reference to FIG. 12) was patterned on a surface of the encapsulation layer TFE through a photolithography and a dry etching process. In the present experimental example, the lens LS on the light emitting elements LD according to each of the manufacturing examples has the same shape.

The color characteristics of light before and after passing through the lenses LS were measured using the manufactured display device 100. The experimental measurement equipment and measurement environment were the same as those in the previous Experiment Example 1.

TABLE 2

| | Before passing through lens | | | After passing through lens | | | — |
|---|---|---|---|---|---|---|---|
| | (LS) | | | (LS) | | | Efficiency |
| | Color | Color | | Color | Color | | improve- |
| | coordi- | coordi- | Conver- | coordi- | coordi- | Conver- | ment |
| | nates | nates | sion | nates | nates | sion | margin |
| — | (x) | (y) | Efficiency | (x) | (y) | Efficiency | (%) |
| Manufac- | 0.23 | 0.727 | 149 | 0.215 | 0.74 | 245 | 164 |
| turing | | | | | | | |
| Example 1 | | | | | | | |
| Manufac- | 0.24 | 0.719 | 142 | 0.223 | 0.733 | 262 | 185 |
| turing | | | | | | | |
| Example 2 | | | | | | | |
| Manufac- | 0.25 | 0.711 | 135 | 0.23 | 0.727 | 273 | 202 |
| turing | | | | | | | |
| Example 3 | | | | | | | |
| Manufac- | 0.26 | 0.703 | 127 | 0.234 | 0.725 | 285 | 224 |
| turing | | | | | | | |
| Example 4 | | | | | | | |
| Manufac- | 0.27 | 0.695 | 119 | 0.241 | 0.72 | 288 | 242 |
| turing | | | | | | | |
| Example 5 | | | | | | | |
| Manufac- | 0.28 | 0.687 | 111 | 0.248 | 0.715 | 275 | 248 |
| turing | | | | | | | |
| Example 6 | | | | | | | |
| Manufac- | 0.29 | 0.679 | 102 | 0.262 | 0.703 | 261 | 256 |
| turing | | | | | | | |
| Example 7 | | | | | | | |
| Manufac- | 0.3 | 0.671 | 88 | 0.275 | 0.692 | 242 | 275 |
| turing | | | | | | | |
| Example 8 | | | | | | | |
| Manufac- | 0.31 | 0.663 | 79 | 0.292 | 0.677 | 212 | 268 |
| turing | | | | | | | |
| Example 9 | | | | | | | |
| Manufac- | 0.32 | 0.655 | 62 | 0.305 | 0.666 | 165 | 266 |
| turing | | | | | | | |
| Example | | | | | | | |
| 10 | | | | | | | |
| Manufac- | 0.33 | 0.647 | 49 | 0.318 | 0.655 | 128 | 261 |
| turing | | | | | | | |
| Example | | | | | | | |
| 11 | | | | | | | |

Referring to Table 2, it can be understood that in the case where the color coordinates fall within a set or specific numeral range, the light emitting efficiency is notably excellent. For example, in the second sub-pixel SP2, in the case where the x-coordinate value of the color coordinates is in a range from approximately 0.23 to approximately 0.275, a display device 100 having a light emitting element LD having excellent light emitting efficiency can be provided.

### 3 Experimental Example 3—Analysis of Light Emitting Efficiency Tendency by Color Coordinates/First Sub-Pixel SP1

### Manufacturing Example 1

A Si wafer substrate (Silicon wafer product from SK Siltron) was provided in a size of 50 mm×50 mm and installed in a vacuum deposition apparatus. A hole injection layer was formed by depositing S-HTL3 to a thickness of 50 Å on an anode electrode AE (Al/TiN) on a glass substrate. A hole transport layer was formed by depositing NPB to a thickness of 1150 Å on the hole injection layer. An electron blocking layer was formed by depositing TCTA to a thickness of 700 Å. Thereafter, an emission layer EML having a thickness of 420 Å was formed on the electron blocking layer by co-depositing TBTI as a host and Ir(dmppy-ph)2(tmd) as a red dopant at a volume ratio of 100:2. A hole blocking layer was formed on the emission layer EML by depositing T2T to a thickness of 50 Å. A hole transport layer having a thickness of 310 Å was formed on the hole blocking layer by co-depositing TMP_TAZ and LiQ at a volume ratio of 1:1. An electron injection layer was formed on the hole transport layer by depositing Yb to a thickness of 10 Å. As a result, an emission structure EMS (e.g., the first emission structure EMS1) was provided. Subsequently, a cathode electrode CE having a thickness of 100 Å was formed on the electron injection layer by co-depositing Ag and Mg at a volume ratio of 9:1 to a thickness of 100 Å. A CPL material (Chemical Formula 1) was formed on the cathode electrode CE, thus leading to the fabrication of a light emitting element LD that can be formed in the first sub-pixel SP1. For reference, commercially marketed materials were used as respective materials for forming the light emitting element LD.

### Manufacturing Example 2

Except for forming TCTA as the electron blocking layer on the hole transport layer to a thickness of 730 Å, a light emitting element LD according to Manufacturing Example 2, which can be formed in the first sub-pixel SP1, was manufactured by the same method as Manufacturing Example 1.

### Manufacturing Example 3

Except for forming TCTA as the electron blocking layer on the hole transport layer to a thickness of 760 Å, a light emitting element LD according to Manufacturing Example 3, which can be formed in the first sub-pixel SP1, was manufactured by the same method as Manufacturing Example 1.

### Manufacturing Example 4

Except for forming TCTA as the electron blocking layer on the hole transport layer to a thickness of 790 Å, a light emitting element LD according to Manufacturing Example 4, which can be formed in the first sub-pixel SP1, was manufactured by the same method as Manufacturing Example 1.

### Manufacturing Example 5

Except for forming TCTA as the electron blocking layer on the hole transport layer to a thickness of 820 Å, a light emitting element LD according to Manufacturing Example 5, which can be formed in the first sub-pixel SP1, was manufactured by the same method as Manufacturing Example 1.

### Manufacturing Example 6

Except for forming TCTA as the electron blocking layer on the hole transport layer to a thickness of 850 Å, a light emitting element LD according to Manufacturing Example 6, which can be formed in the first sub-pixel SP1, was manufactured by the same method as Manufacturing Example 1.

### Manufacturing Example 7

Except for forming TCTA as the electron blocking layer on the hole transport layer to a thickness of 880 Å, a light emitting element LD according to Manufacturing Example 7, which can be formed in the first sub-pixel SP1, was manufactured by the same method as Manufacturing Example 1.

An encapsulation layer TFE was manufactured by successively forming silicon oxide (SiOx)/silicon nitride (SiNx)/silicon oxide (SiOx) through a chemical vapor deposition (CVD) process on the light emitting elements LD manufactured according to each of the manufacturing examples. A lens LS having a circular upper portion (e.g., the lens LS described with reference to FIG. 12) was patterned on a surface of the encapsulation layer TFE through a photolithography and a dry etching process. In the present experimental example, the lens LS on the light emitting elements LD according to each of the manufacturing examples has the same shape.

The color characteristics of light before and after passing through the lenses LS were measured using the manufactured display device 100. The experimental measurement equipment and measurement environment were the same as those in the previous Experiment Examples 1 and 2.

TABLE 3

| | Before passing through lens | | | After passing through lens | | | |
|---|---|---|---|---|---|---|---|
| | (LS) | | | (LS) | | | — |
| | Color | Color | | Color | Color | | Efficiency |
| | coordi- | coordi- | Conver- | coordi- | coordi- | Conver- | improve- |
| | nates | nates | sion | nates | nates | sion | ment margin |
| — | (x) | (y) | Efficiency | (x) | (y) | Efficiency | (%) |
| Manufac- | 0.670 | 0.33 | 32 | 0.663 | 0.337 | 52 | 163 |
| turing | | | | | | | |
| Example 1 | | | | | | | |
| Manufac- | 0.675 | 0.325 | 34 | 0.667 | 0.333 | 63 | 185 |
| turing | | | | | | | |
| Example 2 | | | | | | | |
| Manufac- | 0.680 | 0.32 | 37 | 0.670 | 0.33 | 76 | 205 |
| turing | | | | | | | |
| Example 3 | | | | | | | |
| Manufac- | 0.685 | 0.315 | 36 | 0.672 | 0.328 | 78 | 217 |
| turing | | | | | | | |
| Example 4 | | | | | | | |
| Manufac- | 0.690 | 0.31 | 33 | 0.679 | 0.321 | 72 | 218 |
| turing | | | | | | | |
| Example 5 | | | | | | | |
| Manufac- | 0.695 | 0.305 | 31 | 0.683 | 0.317 | 68 | 219 |
| turing | | | | | | | |
| Example 6 | | | | | | | |
| Manufac- | 0.670 | 0.33 | 28 | 0.678 | 0.322 | 52 | 186 |
| turing | | | | | | | |
| Example 7 | | | | | | | |

Referring to Table 3, it can be understood that in the case where the color coordinates fall within a set or specific numeral range, the light emitting efficiency is notably excellent. For example, in the first sub-pixel SP1, in the case where the x-coordinate value of the color coordinates is in a range from approximately 0.670 to approximately 0.685, a display device 100 having a light emitting element LD having excellent light emitting efficiency can be provided.

### 4 Experimental Example 4—Analysis of Light Emitting Efficiency Tendency According to Shape of Lens LS

### Manufacturing Example 1

A light emitting element LD according to Manufacturing Example 1 was manufactured in the same manner as the light emitting element LD according to Manufacturing Example 4 in Experimental Example 2. An encapsulation layer TFE was provided on the light emitting element LD according to Manufacturing Example 1. A lens LS having a circular upper portion (refer to FIG. 12) was provided on the encapsulation layer TFE, thus providing a display device 100 according to Manufacturing Example 1.

### Manufacturing Example 2

A light emitting element LD according to Manufacturing Example 2 was manufactured in the same manner as the light emitting element LD according to Manufacturing Example 5 in Experimental Example 2. An encapsulation layer TFE was provided on the light emitting element LD according to Manufacturing Example 2. A lens LS having a circular upper portion (refer to FIG. 12) was provided on the encapsulation layer TFE, thus providing a display device 100 according to Manufacturing Example 2.

### Manufacturing Example 3

A light emitting element LD according to Manufacturing Example 3 was manufactured in the same manner as the light emitting element LD according to Manufacturing Example 4 in Experimental Example 2. An encapsulation layer TFE was provided on the light emitting element LD according to Manufacturing Example 3. A lens LS having a circular upper portion (refer to FIG. 12) was provided on the encapsulation layer TFE, thus providing a display device 100 according to Manufacturing Example 3.

### Manufacturing Example 4

A light emitting element LD according to Manufacturing Example 4 was manufactured in the same manner as the light emitting element LD according to Manufacturing Example 5 in Experimental Example 2. An encapsulation layer TFE was provided on the light emitting element LD according to Manufacturing Example 4. A lens LS having a circular upper portion (refer to FIG. 12) was provided on the encapsulation layer TFE, thus providing a display device 100 according to Manufacturing Example 4.

### Manufacturing Example 5

A light emitting element LD according to Manufacturing Example 5 was manufactured in the same manner as the light emitting element LD according to Manufacturing Example 4 in Experimental Example 2. An encapsulation layer TFE was provided on the light emitting element LD according to Manufacturing Example 5. A lens LS having a circular upper portion (refer to FIG. 12) was provided on the encapsulation layer TFE, thus providing a display device 100 according to Manufacturing Example 5.

### Manufacturing Example 6

A light emitting element LD according to Manufacturing Example 6 was manufactured in the same manner as the light emitting element LD according to Manufacturing Example 5 in Experimental Example 2. An encapsulation layer TFE was provided on the light emitting element LD according to Manufacturing Example 6. A lens LS having a circular upper portion (refer to FIG. 12) was provided on the encapsulation layer TFE, thus providing a display device 100 according to Manufacturing Example 6.

### Manufacturing Example 7

A light emitting element LD according to Manufacturing Example 7 was manufactured in the same manner as the light emitting element LD according to Manufacturing Example 4 in Experimental Example 2. An encapsulation layer TFE was provided on the light emitting element LD according to Manufacturing Example 7. A lens LS having a circular upper portion (refer to FIG. 12) was provided on the encapsulation layer TFE, thus providing a display device 100 according to Manufacturing Example 7.

### Manufacturing Example 8

A light emitting element LD according to Manufacturing Example 8 was manufactured in the same manner as the light emitting element LD according to Manufacturing Example 5 in Experimental Example 2. An encapsulation layer TFE was provided on the light emitting element LD according to Manufacturing Example 8. A lens LS having a circular upper portion (refer to FIG. 12) was provided on the encapsulation layer TFE, thus providing a display device 100 according to Manufacturing Example 8.

The color characteristics of light before and after passing through the lenses LS were measured using the manufactured display device 100. The experimental measurement equipment and measurement environment were the same as those in the previous Experiment Example 1.

TABLE 4

| | Before passing through lens | | | After passing through lens | | | |
|---|---|---|---|---|---|---|---|
| | (LS) | | | (LS) | | | — |
| | Color | Color | | Color | Color | | Efficiency |
| | coordi- | coordi- | Conver- | coordi- | coordi- | Conver- | improve- |
| | nates | nates | sion | nates | nates | sion | ment margin |
| — | (x) | (y) | Efficiency | (x) | (y) | Efficiency | (%) |
| Manufac- | 0.260 | 0.703 | 135 | 0.253 | 0.71 | 212 | 157 |
| turing | | | | | | | |
| Example 1 | | | | | | | |
| Manufac- | 0.270 | 0.695 | 127 | 0.263 | 0.702 | 215 | 169 |
| turing | | | | | | | |
| Example 2 | | | | | | | |
| Manufac- | 0.260 | 0.703 | 135 | 0.252 | 0.711 | 222 | 164 |
| turing | | | | | | | |
| Example 3 | | | | | | | |
| Manufac- | 0.270 | 0.695 | 127 | 0.264 | 0.702 | 215 | 169 |
| turing | | | | | | | |
| Example 4 | | | | | | | |
| Manufac- | 0.260 | 0.703 | 135 | 0.231 | 0.726 | 273 | 202 |
| turing | | | | | | | |
| Example 5 | | | | | | | |
| Manufac- | 0.270 | 0.695 | 127 | 0.236 | 0.723 | 285 | 224 |
| turing | | | | | | | |
| Example 6 | | | | | | | |
| Manufac- | 0.260 | 0.703 | 135 | 0.233 | 0.725 | 274 | 203 |
| turing | | | | | | | |
| Example 7 | | | | | | | |
| Manufac- | 0.270 | 0.695 | 127 | 0.237 | 0.723 | 282 | 222 |
| turing | | | | | | | |
| Example 8 | | | | | | | |

Referring to Table 4, it can be understood that in the case where the lens LS has a trapezoidal cross-section in the lower lens part LS_B and has a semi-circular cross-section in the upper lens part LS_U (refer to FIG. 12), the color coordinates of light when passing through the lens LS may be further shifted in a short wavelength direction, thus indicating notably excellent light emitting efficiency.

### 5 Experimental Example 5—Analysis of Light Emitting Efficiency Tendency According to Thickness of Cathode Electrode CE

### Manufacturing Example 1

Except for forming the cathode electrode CE to a thickness of 50 Å, a light emitting element LD according to Manufacturing Example 1 was manufactured in the same manner as the light emitting element LD according to Manufacturing Example 5 in Experimental Example 2. An encapsulation layer TFE was provided on the light emitting element LD according to Manufacturing Example 1. A lens LS having a circular upper portion (refer to FIG. 12) was provided on the encapsulation layer TFE, thus providing a display device 100 according to Manufacturing Example 1.

### Manufacturing Example 2

Except for forming the cathode electrode CE to a thickness of 60 Å, a light emitting element LD according to Manufacturing Example 2 was manufactured in the same manner as the light emitting element LD according to Manufacturing Example 5 in Experimental Example 2. An encapsulation layer TFE was provided on the light emitting element LD according to Manufacturing Example 2. A lens LS having a circular upper portion (refer to FIG. 12) was provided on the encapsulation layer TFE, thus providing a display device 100 according to Manufacturing Example 2.

### Manufacturing Example 3

Except for forming the cathode electrode CE to a thickness of 70 Å, a light emitting element LD according to Manufacturing Example 3 was manufactured in the same manner as the light emitting element LD according to Manufacturing Example 5 in Experimental Example 2. An encapsulation layer TFE was provided on the light emitting element LD according to Manufacturing Example 2. A lens LS having a circular upper portion (refer to FIG. 12) was provided on the encapsulation layer TFE, thus providing a display device 100 according to Manufacturing Example 3.

### Manufacturing Example 4

Except for forming the cathode electrode CE to a thickness of 80 Å, a light emitting element LD according to Manufacturing Example 4 was manufactured in the same manner as the light emitting element LD according to Manufacturing Example 5 in Experimental Example 2. An encapsulation layer TFE was provided on the light emitting element LD according to Manufacturing Example 4. A lens LS having a circular upper portion (refer to FIG. 12) was provided on the encapsulation layer TFE, thus providing a display device 100 according to Manufacturing Example 4.

### Manufacturing Example 5

Except for forming the cathode electrode CE to a thickness of 90 Å, a light emitting element LD according to Manufacturing Example 5 was manufactured in the same manner as the light emitting element LD according to Manufacturing Example 5 in Experimental Example 2. An encapsulation layer TFE was provided on the light emitting element LD according to Manufacturing Example 5. A lens LS having a circular upper portion (refer to FIG. 12) was provided on the encapsulation layer TFE, thus providing a display device 100 according to Manufacturing Example 5.

### Manufacturing Example 6

Except for forming the cathode CE electrode to a thickness of 100 Å, a light emitting element LD according to Manufacturing Example 6 was manufactured in the same manner as the light emitting element LD according to Manufacturing Example 5 in Experimental Example 2. An encapsulation layer TFE was provided on the light emitting element LD according to Manufacturing Example 6. A lens LS having a circular upper portion (refer to FIG. 12) was provided on the encapsulation layer TFE, thus providing a display device 100 according to Manufacturing Example 6.

### Manufacturing Example 7

Except for forming the cathode electrode CE to a thickness of 110 Å, a light emitting element LD according to Manufacturing Example 7 was manufactured in the same manner as the light emitting element LD according to Manufacturing Example 5 in Experimental Example 2. An encapsulation layer TFE was provided on the light emitting element LD according to Manufacturing Example 7. A lens LS having a circular upper portion (refer to FIG. 12) was provided on the encapsulation layer TFE, thus providing a display device 100 according to Manufacturing Example 7.

### Manufacturing Example 8

Except for forming the cathode electrode CE to a thickness of 120 Å, a light emitting element LD according to Manufacturing Example 8 was manufactured in the same manner as the light emitting element LD according to Manufacturing Example 5 in Experimental Example 2. An encapsulation layer TFE was provided on the light emitting element LD according to Manufacturing Example 8. A lens LS having a circular upper portion (refer to FIG. 12) was provided on the encapsulation layer TFE, thus providing a display device 100 according to Manufacturing Example 8.

### Manufacturing Example 9

Except for forming the cathode electrode CE to a thickness of 130 Å, a light emitting element LD according to Manufacturing Example 9 was manufactured in the same manner as the light emitting element LD according to Manufacturing Example 5 in Experimental Example 2. An encapsulation layer TFE was provided on the light emitting element LD according to Manufacturing Example 9. A lens LS having a circular upper portion (refer to FIG. 12) was provided on the encapsulation layer TFE, thus providing a display device 100 according to Manufacturing Example 9.

### Manufacturing Example 10

Except for forming the cathode electrode CE to a thickness of 140 Å, a light emitting element LD according to Manufacturing Example 10 was manufactured in the same manner as the light emitting element LD according to Manufacturing Example 5 in Experimental Example 2. An encapsulation layer TFE was provided on the light emitting element LD according to Manufacturing Example 10. A lens LS having a circular upper portion (refer to FIG. 12) was provided on the encapsulation layer TFE, thus providing a display device 100 according to Manufacturing Example 10.

### Manufacturing Example 11

Except for forming the cathode electrode CE to a thickness of 150 Å, a light emitting element LD according to Manufacturing Example 11 was manufactured in the same manner as the light emitting element LD according to Manufacturing Example 5 in Experimental Example 2. An encapsulation layer TFE was provided on the light emitting element LD according to Manufacturing Example 11. A lens LS having a circular upper portion (refer to FIG. 12) was provided on the encapsulation layer TFE, thus providing a display device 100 according to Manufacturing Example 11.

### Manufacturing Example 12

Except for forming the cathode electrode CE to a thickness of 160 Å, a light emitting element LD according to Manufacturing Example 12 was manufactured in the same manner as the light emitting element LD according to Manufacturing Example 5 in Experimental Example 2. An encapsulation layer TFE was provided on the light emitting element LD according to Manufacturing Example 12. A lens LS having a circular upper portion (refer to FIG. 12) was provided on the encapsulation layer TFE, thus providing a display device 100 according to Manufacturing Example 12.

### Manufacturing Example 13

Except for forming the cathode electrode CE to a thickness of 170 Å, a light emitting element LD according to Manufacturing Example 13 was manufactured in the same manner as the light emitting element LD according to Manufacturing Example 5 in Experimental Example 2. An encapsulation layer TFE was provided on the light emitting element LD according to Manufacturing Example 13. A lens LS having a circular upper portion (refer to FIG. 12) was provided on the encapsulation layer TFE, thus providing a display device 100 according to Manufacturing Example 13.

The color characteristics of light before and after passing through the lenses LS were measured using the manufactured display device 100. The experimental measurement equipment and measurement environment were the same as those in the previous Experiment Example 1.

TABLE 5

| | Before passing through lens | | | After passing through lens | | | |
|---|---|---|---|---|---|---|---|
| | (LS) | | | (LS) | | | — |
| | Color | Color | | Color | Color | | Efficiency |
| | coordi- | coordi- | Conver- | coordi- | coordi- | Conver- | improve- |
| | nates | nates | sion | nates | nates | sion | ment margin |
| — | (x) | (y) | Efficiency | (x) | (y) | Efficiency | (%) |
| Manufac- | 0.301 | 0.671 | 128 | 0.284 | 0.685 | 218 | 170 |
| turing | | | | | | | |
| Example 1 | | | | | | | |
| Manufac- | 0.294 | 0.677 | 123 | 0.276 | 0.692 | 231 | 188 |
| turing | | | | | | | |
| Example 2 | | | | | | | |
| Manufac- | 0.286 | 0.684 | 119 | 0.264 | 0.703 | 245 | 206 |
| turing | | | | | | | |
| Example 3 | | | | | | | |
| Manufac- | 0.281 | 0.688 | 116 | 0.258 | 0.708 | 258 | 222 |
| turing | | | | | | | |
| Example 4 | | | | | | | |
| Manufac- | 0.278 | 0.69 | 114 | 0.254 | 0.711 | 268 | 235 |
| turing | | | | | | | |
| Example 5 | | | | | | | |
| Manufac- | 0.275 | 0.692 | 113 | 0.246 | 0.718 | 275 | 243 |
| turing | | | | | | | |
| Example 6 | | | | | | | |
| Manufac- | 0.271 | 0.695 | 107 | 0.243 | 0.72 | 252 | 236 |
| turing | | | | | | | |
| Example 7 | | | | | | | |
| Manufac- | 0.266 | 0.698 | 102 | 0.241 | 0.72 | 221 | 217 |
| turing | | | | | | | |
| Example 8 | | | | | | | |
| Manufac- | 0.261 | 0.701 | 95 | 0.237 | 0.722 | 201 | 212 |
| turing | | | | | | | |
| Example 9 | | | | | | | |
| Manufac- | 0.252 | 0.708 | 89 | 0.230 | 0.727 | 185 | 208 |
| turing | | | | | | | |
| Example | | | | | | | |
| 10 | | | | | | | |
| Manufac- | 0.241 | 0.717 | 82 | 0.226 | 0.729 | 154 | 188 |
| turing | | | | | | | |
| Example | | | | | | | |
| 11 | | | | | | | |
| Manufac- | 0.230 | 0.726 | 72 | 0.223 | 0.73 | 128 | 178 |
| turing | | | | | | | |
| Example | | | | | | | |
| 12 | | | | | | | |
| Manufac- | 0.221 | 0.733 | 68 | 0.217 | 0.734 | 111 | 163 |
| turing | | | | | | | |
| Example | | | | | | | |
| 13 | | | | | | | |

Referring to Table 5, it can be understood that in the case where the thickness of the cathode electrode CE falls within a set or certain numeral range, the light emitting efficiency is notably excellent. For example, in the case where the thickness of the cathode electrode CE is in a range from approximately 70 Å to approximately 140 Å, a display device 100 having a light emitting element LD having excellent light emitting efficiency can be provided.

Although specific embodiments and example embodiments have been described, it should be noted that other embodiments and modifications may be derived from the disclosure provided. Accordingly, the concepts of the present disclosure are not limited to the foregoing embodiments, but rather includes the broader scope of the presented claims and various obvious modifications and equivalent arrangements.

Various embodiments of the present disclosure may provide a display device having excellent color quality.

Various embodiments of the present disclosure may provide a display device having enhanced light output efficiency and light emitting efficiency.

Various embodiments of the present disclosure may provide a display device in which light output information may be defined in suitable or desired color coordinates, so that the reliability of the light output information can be improved.

Various embodiments of the present disclosure may provide a display system capable of providing aforementioned technical effects.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims, and equivalents thereof.

1. A display device, comprising:
a light-emitting-element layer on a substrate, and comprising an anode electrode, a cathode electrode, a first sub-pixel comprising a first emission structure, a second sub-pixel comprising a second emission structure, and a third sub-pixel comprising a third emission structure; and
a lens-array layer on the light-emitting-element layer, and comprising lenses comprising a first lens provided to overlap the first emission structure in a plan view, a second lens provided to overlap the second emission structure in a plan view, and a third lens provided to overlap the third emission structure in a plan view,
wherein in the first sub-pixel, a first base light provided from the first emission structure passes through the first lens and is provided as a first light,
wherein in the second sub-pixel, a second base light provided from the second emission structure passes through the second lens and is provided as a second light,
wherein in the third sub-pixel, a third base light provided from the third emission structure passes through the third lens and is provided as a third light,
wherein an x-coordinate value of International Commission on Illumination (CIE) color coordinates of the first base light is in a range from 0.680 to 0.695, an x-coordinate value of CIE color coordinates of the second base light is in a range from 0.250 to 0.295, and a y-coordinate value of CIE color coordinates of the third base light is in a range from 0.060 to 0.100, and
wherein an x-coordinate value of CIE color coordinates of the first light is in a range from 0.670 to 0.685, an x-coordinate value of CIE color coordinates of the second light is in a range from 0.230 to 0.265, and a y-coordinate value of CIE color coordinates of the third light is in a range from 0.040 to 0.060.

2. The display device according to claim 1,
wherein the first light is red light,
wherein the second light is green light,
wherein the third light is blue light, and
wherein the display device comprises the first sub-pixel configured to provide the red light, the second sub-pixel configured to provide the green light, and the third sub-pixel configured to provide the blue light without including a color filter.

3. The display device according to claim 1,
wherein each of the first emission structure, the second emission structure, and the third emission structure comprises a hole transport part, an electron transport part, and an emission layer between the hole transport part and the electron transport part,
wherein the emission layer comprises a first emission layer included in the first emission structure, a second emission layer included in the second emission structure, and a third emission layer included in the third emission structure,
wherein the emission element layer further comprises a capping layer on the cathode electrode,
wherein the respective electron transport parts of the first emission structure, the second emission structure, and the third emission structure comprise a same material, and
wherein the hole transport part of the third emission structure has a material at least partially different from the hole transport part of each of the first emission structure and the second emission structure.

4. The display device according to claim 3,
wherein the capping layer comprises a CPL material (Chemical Formula 1),
wherein the hole transport part comprises one or more selected from the group consisting of m-MTDATA (Chemical Formula 2), NPB (Chemical Formula 3), TCTA (Chemical Formula 4), S-HTL1 (Chemical Formula 5), S-HTL2 (Chemical Formula 6), S-HTL3 (Chemical Formula 7), S-HTL4 (Chemical Formula 8), and NDP-9 (Chemical Formula 9),
wherein the first emission layer comprises TPBI (Chemical Formula 10) as a host and comprises Ir(dmppy-ph)2(tmd) (Chemical Formula 11) as a red dopant,
wherein the second emission layer comprises TBTI as a host and comprises Irppy3 (Chemical Formula 12) as a green dopant,
wherein the third emission layer comprises a blue host (Chemical Formula 13) as a host and comprises a blue dopant (Chemical Formula 14), and
wherein the electron transport part comprises one or more selected from the group consisting of T2T (Chemical Formula 15), TPM-TAZ (Chemical Formula 16), LiQ (lithium quinolate) (Chemical Formula 17), and Yb.

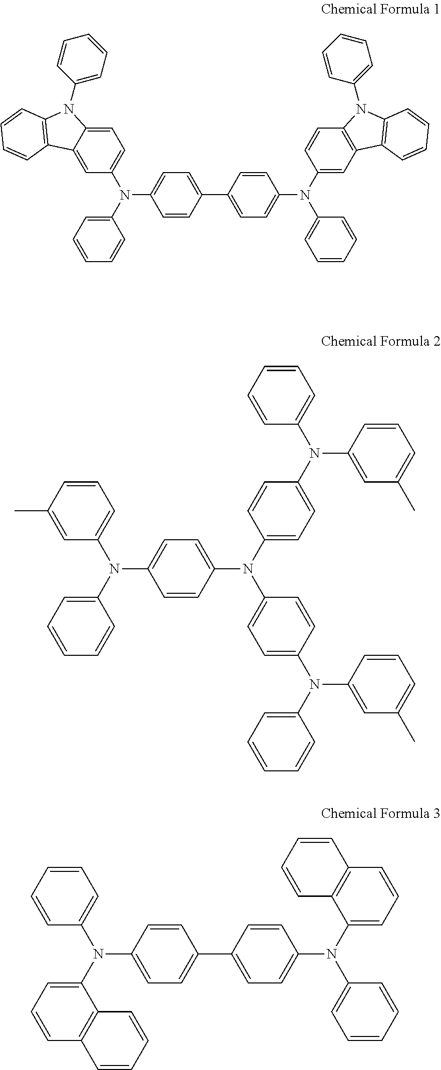

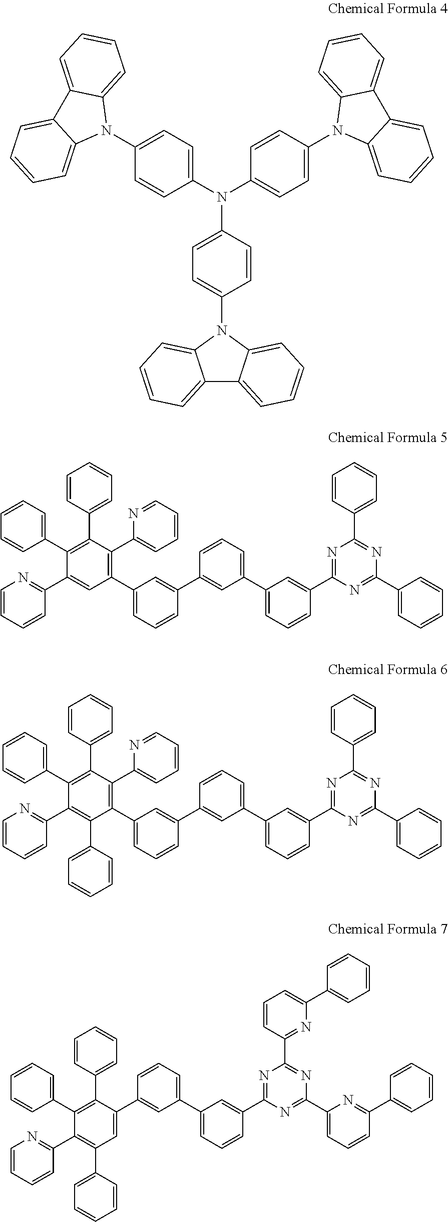 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc(-c2nc(-c3ccccc3)nc(-c3cccc(-c4cccc(-c5cccc(-c6cc(-c7ccccn7)c(-c7ccccc7)c(-c7ccccc7)c6-c6ccccn6)c5)c4)c3)n2)cc1 ; c1ccc(-c2nc(-c3ccccc3)nc(-c3cccc(-c4cccc(-c5cccc(-c6c(-c7ccccc7)c(-c7ccccn7)c(-c7ccccc7)c(-c7ccccc7)c6-c6ccccn6)c5)c4)c3)n2)cc1 ; c1ccc(-c2cccc(-c3nc(-c4cccc(-c5cccc(-c6cc(-c7ccccc7)c(-c7ccccn7)c(-c7ccccc7)c6-c6ccccc6)c5)c4)nc(-c4cccc(-c5ccccc5)n4)n3)n2)cc1]

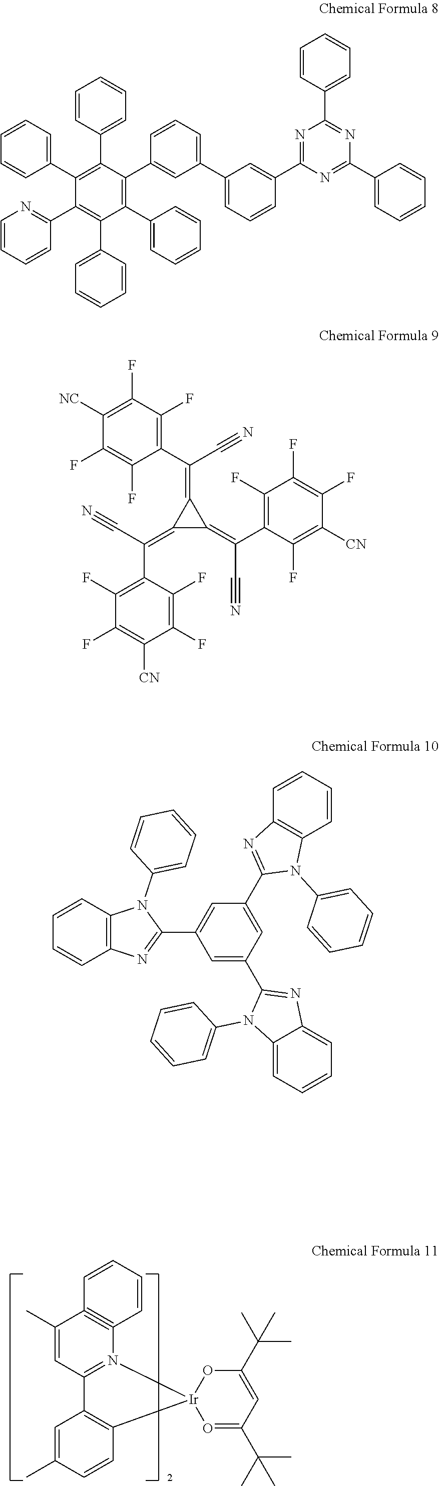

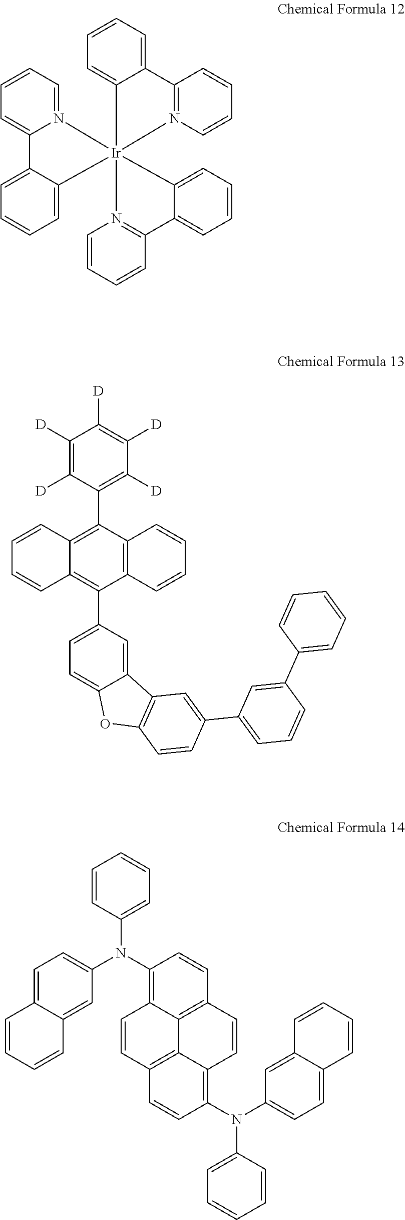

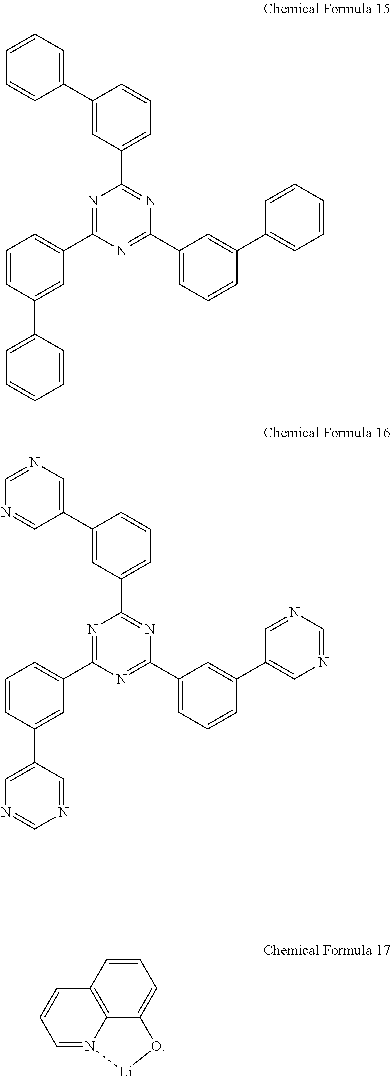

5. The display device according to claim 3,
wherein the hole transport part of the first emission structure comprises a first hole injection layer, a first hole transport layer on the first hole injection layer, and a first electron blocking layer on the first hole transport layer,
wherein the hole transport part of the second emission structure comprises a second hole injection layer, a second hole transport layer on the second hole injection layer, and a second electron blocking layer on the second hole transport layer,
wherein the hole transport part of the third emission structure comprises a third hole injection layer, a third hole transport layer on the third hole injection layer, and a third electron blocking layer on the third hole transport layer, and
wherein the electron transport part of each of the first emission structure, the second emission structure, and the third emission structure comprises: a hole blocking layer, an electron transport layer on the hole blocking layer, and an electron injection layer on the electron transport layer.

6. The display device according to claim 5,
wherein each of the first hole injection layer and the second hole injection layer has a thickness in a range from 25 Å to 75 Å,
wherein each of the first hole transport layer and the second hole transport layer has a thickness in a range from 800 Å to 1500 Å,
wherein the first electron blocking layer has a thickness in a range from 700 Å to 900 Å,
wherein the second electron blocking layer has a thickness in a range from 350 Å to 600 Å,
wherein the third hole injection layer has a thickness in a range from 25 Å to 75 Å,
wherein the third hole transport layer has a thickness in a range from 1150 Å to 1300 Å, and
wherein the third electron blocking layer has a thickness in a range from 25 Å to 75 Å.

7. The display device according to claim 5,
wherein the first emission layer has a thickness in a range from 320 Å to 520 Å,
wherein the second emission layer has a thickness in a range from 280 Å to 480 Å, and
wherein the third emission layer has a thickness in a range from 150 Å to 250 Å.

8. The display device according to claim 5,
wherein in each of the first emission structure, the second emission structure, and the third emission structure,
the hole blocking layer has a thickness in a range from 25 Å to 75 Å,
the electron transport layer has a thickness in a range from 250 Å to 370 Å, and
the electron injection layer has a thickness in a range from 7 Å to 13 Å.

9. The display device according to claim 1, further comprising an overcoat layer on the lens-array layer,
wherein the lenses have a refractive index higher than the overcoat layer.

10. The display device according to claim 1, wherein the lenses comprise one or more selected from the group consisting of acryl resin, epoxy resin, phenolic resin, polyamide resin, polyimide resin, polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polycarbonate (PC), cellulose triacetate (CAT), and cellulose acetate propionate (CAP).

11. The display device according to claim 1,
wherein each of the lenses has a side surface, and
wherein the side surface forms an included angle in a range from 50° to 70° with respect to a base on which the lens array layer is provided.

12. The display device according to claim 1, wherein each of the lenses has a semi-circular cross-section.

13. The display device according to claim 1, wherein each of the lenses has a trapezoidal cross-section.

14. The display device according to claim 1,
wherein each of the lenses comprises a lower lens part and an upper lens part on the lower lens part,
wherein the lower lens part has a first trapezoidal cross-section, and
wherein the upper lens part has a second trapezoidal cross-section that is not in a similar geometric relationship with the first trapezoidal cross-section.

15. The display device according to claim 1,
wherein each of the lenses comprises a lower lens part and an upper lens part disposed on the lower lens part,
wherein the lower lens part has a trapezoidal cross-section, and
wherein the upper lens part has a semi-circular cross-section.

16. The display device according to claim 1, wherein the cathode electrode has a thickness in a range from 70 Å to 140 Å.

17. The display device according to claim 16, wherein the cathode electrode comprises at least one of silver (Ag), magnesium (Mg), and a compound thereof.

18. The display device according to claim 1, wherein the substrate comprises a silicon wafer substrate.

19. A display device, comprising:
a light-emitting-element layer on a substrate, and comprising an anode electrode, a cathode electrode, a first sub-pixel comprising a first emission structure, a second sub-pixel comprising a second emission structure, and a third sub-pixel comprising a third emission structure; and
a lens-array layer on the light-emitting-element layer, and comprising lenses comprising a first lens provided to overlap the first emission structure in a plan view, a second lens provided to overlap the second emission structure in a plan view, and a third lens provided to overlap the third emission structure in a plan view,
wherein each of the lenses comprises a lower lens part and an upper lens part on the lower lens part,
wherein the lower lens part has a trapezoidal cross-section, and
wherein the upper lens part has a semi-circular cross-section.

20. A display device, comprising:
a light-emitting-element layer on a substrate, and comprising an anode electrode, a cathode electrode, a first sub-pixel comprising a first emission structure, a second sub-pixel comprising a second emission structure, and a third sub-pixel comprising a third emission structure; and
a lens-array layer on the light-emitting-element layer, and comprising lenses comprising a first lens provided to overlap the first emission structure in a plan view, a second lens provided to overlap the second emission structure in a plan view, and a third lens provided to overlap the third emission structure in a plan view,
wherein the display device comprises the first sub-pixel, the second sub-pixel, and the third sub-pixel without including a color filter, and
wherein the cathode electrode comprises a same material in each of the first emission structure, the second emission structure, and the third emission structure, and has a thickness in a range from 70 Å to 140 Å.
